(19) United States
(12) Patent Application Publication
(10) Pub. No.: US 2024/0421140 A1
(43) Pub. Date: Dec. 19, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Sanghoon Lee, Suwon-si (KR); Yeongbeom Ko, Suwon-si (KR); Seokgeun Ahn, Suwon-si (KR); Juhyeon Oh, Suwon-si (KR); Gwangjae Jeon, Suwon-si (KR)

(21) Appl. No.: 18/628,182

(22) Filed: Apr. 5, 2024

(30) Foreign Application Priority Data
Jun. 14, 2023 (KR) 10-2023-0076174

(51) Int. Cl. H01L 25/18; H01L 23/00; H01L 23/31; H01L 23/48

(52) U.S. Cl. CPC H01L 25/18; H01L 23/3185; H01L 23/481; H01L 24/08; H01L 2224/08145; H01L 2224/80; H01L 2224/80895; H01L 2224/80896; H01L 2924/1436

(57) ABSTRACT

A semiconductor package includes a buffer die, a first core die stack stacked on the buffer die, the first core die stack including at least one first intermediate core and a first gap filling portion covering an outer surface of the at least one first intermediate core, and a second core die stack stacked on the first core die stack, the second core die stack including at least one second intermediate core and a second gap filling portion covering an outer surface of the at least one second intermediate core. The first gap filling portion and the second gap filling portion are directly bonded to each other.

### CROSS-REFERENCE TO RELATED APPLICATION

This application claims priority under 35 U.S.C. § 119 to Korean Patent Application No. 10-2023-0076174, filed on Jun. 14, 2023 in the Korean Intellectual Property Office (KIPO), the contents of which are herein incorporated by reference in its entirety.

### TECHNICAL FIELD

This disclosure relates to a semiconductor package and a method of manufacturing the semiconductor package. More particularly, the semiconductor package can include a plurality of sequentially stacked semiconductor chips and a method of manufacturing the same.

### BACKGROUND

To manufacture a multi-chip package in which at least four semiconductor chips are stacked, in a die to wafer bonding process, pad-to-pad direct bonding may be performed without using solder bumps. In this case, as the number of stacked chips increases, unbonded areas (voids) may occur due to accumulation of bonding interface topology, resulting in deterioration of the bonding quality between the interfaces bonding in hybrid bonding.

### SUMMARY

In general, aspects of the subject matter described in this specification can be embodied in a semiconductor package including: a buffer die, a first core die stack stacked on the buffer die, the first core die stack including at least one first intermediate core and a first gap filling portion covering an outer surface of the at least one first intermediate core, and a second core die stack stacked on the first core die stack, the second core die stack including at least one second intermediate core and a second gap filling portion covering an outer surface of the at least one second intermediate core. The first gap filling portion and the second gap filling portion are directly bonded to each other.

Another general aspect can be embodied in a semiconductor package including: a buffer die, a first core die stack stacked on the buffer die, the first core die stack including at least one first intermediate core and a first gap filling portion covering an outer surface of the at least one first intermediate core, a second core die stack stacked on the first core die stack, the second core die stack including at least one second intermediate core and a second gap filling portion covering an outer surface of the at least one second intermediate core, and a top core die stack on the second core die stack, the top core die stack including a top core and a third gap filling portion covering an outer surface of the top core. Each of the at least one first intermediate core and the at least one second intermediate core includes a substrate, a front insulating layer provided on a front surface of the substrate and having a first bonding pad provided therein, and a backside insulating layer provided on a backside surface of the substrate and having a second bonding pad provided therein. The first gap filling portion and the second gap filling portion are directly bonded to each other.

Another general aspect can be embodied in a semiconductor package including: a buffer die, a plurality of core die stacks sequentially stacked on the buffer die, and a top core die stack stacked on an uppermost core die stack of the plurality of core die stacks. Each of the plurality of core die stacks includes at least one intermediate core and a gap filling portion covering an outer surface of the at least one intermediate core. The at least one intermediate core includes a substrate, a front insulating layer provided on a front surface of the substrate and having a first bonding pad provided therein, and a backside insulating layer provided on a backside surface of the substrate and having a second bonding pad provided therein.

Another general aspect can be embodied in a method of manufacturing a semiconductor package, where a first wafer including a buffer die formed therein is provided. A first reconstructed wafer including at least one first intermediate core and a first gap filling portion that covers an outer surface of the at least one intermediate core is formed on the first wafer. A second reconstructed wafer including at least second intermediate core and a second gap filling portion that covers an outer surface of the at least one second intermediate core is formed on a carrier substrate. The second reconstructed wafer is stacked on the first reconstructed wafer. The first gap fill portion and the second gap fill portion are directly bonded to each other.

In some implementations, a semiconductor package may include a plurality of core die stacks and a top core die stack sequentially stacked on a buffer die. Each of the core die stacks may include at least one intermediate core and a gap filling portion that covers an outer surface of the at least one intermediate core. The core die stacks may be bonded to each other through hybrid bonding. The gap filling portion of the core die stacks may be directly bonded to each other.

Each time each of the plurality of core die stacks is stacked, upper surfaces of uppermost intermediate cores may be planarized to initialize topology due to the stacking of the intermediate cores.

Accordingly, it may be possible to prevent voids from occurring at the bonding interface due to accumulation of bonding interface topology during high-level chip stacking. Thus, by using the wafer-to-wafer bonding method, costs due to an increase in the topology initialization process using a wafer support system may be reduced.

### BRIEF DESCRIPTION OF THE DRAWINGS

FIG. 1 is a cross-sectional view illustrating an example of a semiconductor package.

FIG. 2 is an enlarged cross-sectional view illustrating portion ‘A’ in FIG. 1.

FIG. 3 is an enlarged cross-sectional view illustrating portion ‘B’ in FIG. 1.

FIG. 4 is an enlarged cross-sectional view illustrating portion ‘C’ in FIG. 1.

FIGS. 5 to 28 are views illustrating an example of a method of manufacturing a semiconductor package.

FIG. 29 is a cross-sectional view illustrating an example of a semiconductor package.

FIGS. 30 to 35 are views illustrating an example of a method of manufacturing a semiconductor package.

### DETAILED DESCRIPTION

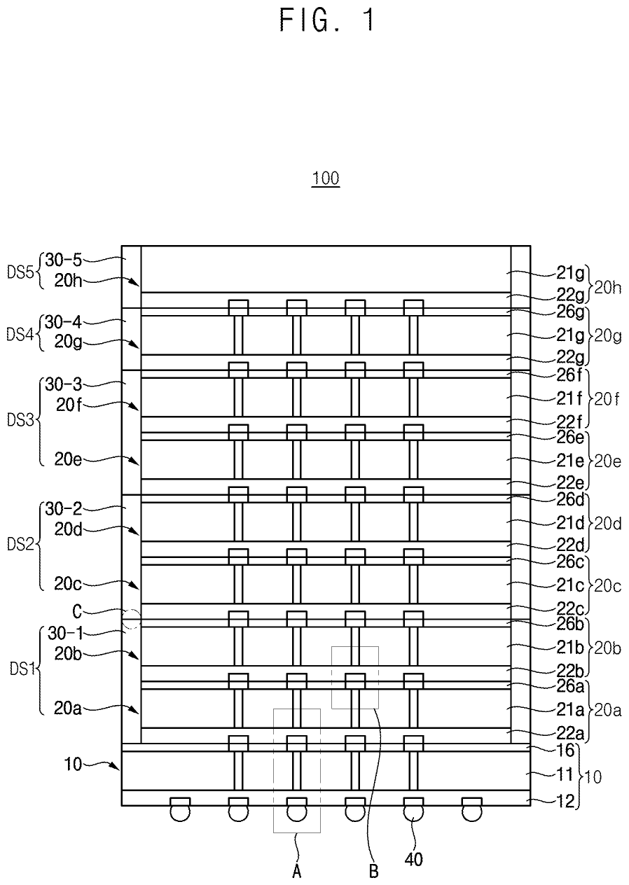

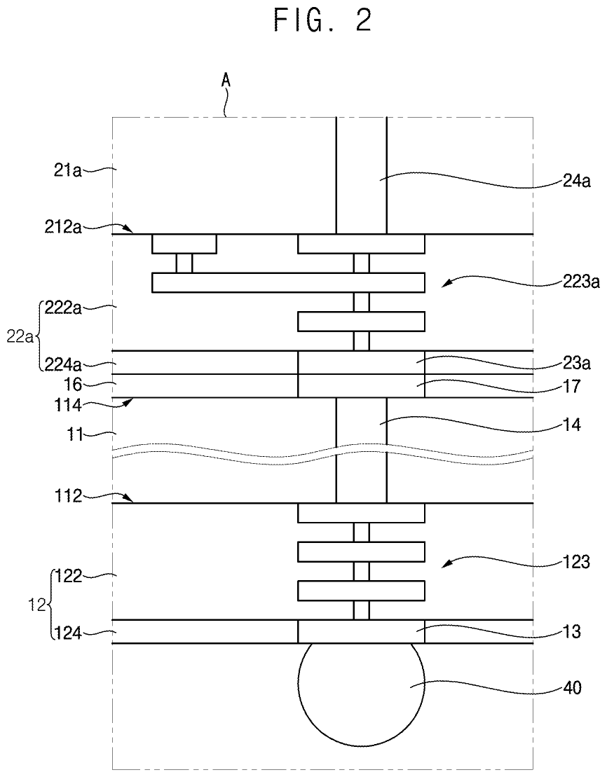

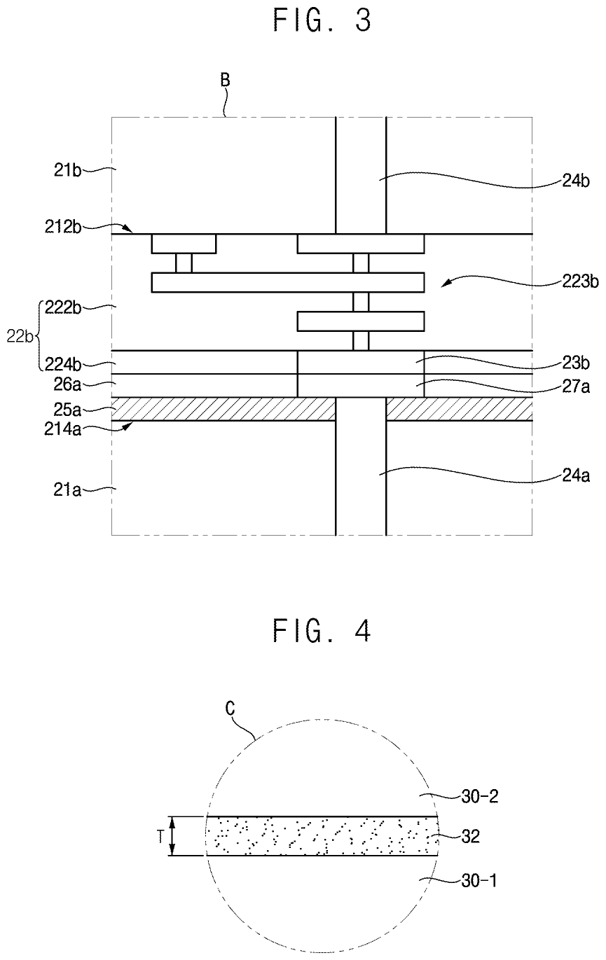

FIG. 1 is a cross-sectional view illustrating a semiconductor package. FIG. 2 is an enlarged cross-sectional view illustrating portion ‘A’ in FIG. 1. FIG. 3 is an enlarged cross-sectional view illustrating portion ‘B’ in FIG. 1. FIG. 4 is an enlarged cross-sectional view illustrating portion ‘C’ in FIG. 1.

Referring to FIGS. 1 to 4, a semiconductor package 100 includes semiconductor chips (core dies) 20 stacked therein. The semiconductor package 100 includes a buffer die 10, and first to fourth core die stacks DS1, DS2, DS3, and DS4 and a top core die stack DS5 sequentially stacked on the buffer die 10.

A plurality of semiconductor chip cores (dies) 20a, 20b, 20c, 20d, 20e, 20f, 20g, and 20h are stacked vertically. In this example, the semiconductor chips (dies) 20a, 20b, 20c, 20d, 20e, 20f, 20g, and 20h are substantially the same as or similar to each other. Accordingly, same or like reference numerals will be used to refer to the same or like elements and repeated descriptions of the same elements may be omitted.

In this example, the semiconductor package as a multi-chip package is illustrated as including eight stacked semiconductor chips, e.g., cores 20a, 20b, 20c, 20d, 20e, 20f, 20g, and 20h, on the buffer die 10, however, the number is not limited thereto. For example, the semiconductor package may include 4, 12, or 16 stacked semiconductor chips.

Each of the semiconductor chips, e.g., cores 20a, 20b, 20c, 20d, 20e, 20f, 20g and 20h, may include an integrated circuit chip completed by performing semiconductor manufacturing processes. Each semiconductor chip may include, for example, a memory chip or a logic chip. The semiconductor package 100 may include a memory device. The memory device may include a high bandwidth memory (HBM) device.

In some implementations, a buffer die 10 may include a substrate 11, a front insulating layer 12, a plurality of first bonding pads 13, a plurality of through electrodes 14, and a backside insulating layer 16, and a plurality of second bonding pads 17. Additionally, the buffer die 10 may further include conductive bumps 40 as conductive connection members respectively provided on the first bonding pads 13. The buffer die 10 may be mounted on a package substrate or an interposer via the conductive bumps 40. For example, the conductive bump 40 may include a solder bump. Alternatively, the conductive bump 40 may include a pillar bump and a solder bump formed on the pillar bump.

The substrate 11 may have a first surface 112 and a second surface 114 opposite to the first surface 112. The first surface 112 may be an active surface, and the second surface 114 may be a non-active surface. Circuit patterns may be provided on the first surface 112 of the substrate 11. The first surface 112 may be referred to as a front surface on which the circuit patterns are formed, and the second surface may be referred to as a backside surface.

For example, the substrate 11 may be a single crystal silicon substrate. The circuit patterns may include transistors, capacitors, diodes, and other suitable/desired components. The circuit patterns may constitute circuit elements. Accordingly, the buffer die 10 may be a semiconductor device having a plurality of circuit elements formed therein.

As illustrated in FIG. 2, the front insulating layer 12 as an insulation interlayer is formed on the first surface 112 of the substrate 11, e.g., the front surface. The front insulating layer 12 includes a plurality of insulating layers 222 and 224 and wirings 123 in the insulating layers. Additionally, the first bonding pad 13 may be provided in an outermost insulating layer of the front insulating layer 12.

For example, the front insulating layer 12 may include a metal wiring layer 122 and a first passivation layer 124. The metal wiring layer 122 may include a plurality of wirings 123 therein. For example, the metal wiring layer 122 may include a metal interconnection structure including a plurality of wirings 123 vertically stacked in buffer layers and insulating layers. The first bonding pad 13 may be formed on an uppermost wiring among the plurality of wirings 123. For example, the wirings may include aluminum (Al), copper (Cu), tin (Sn), nickel (Ni), gold (Au), platinum (Pt), or alloys thereof.

The first passivation layer 124 may be formed on the metal wiring layer 122 and may expose at least a portion of the first bonding pad 13. The first passivation layer 124 may include a plurality of stacked insulating layers. For example, the first passivation layer 224 may include a first protective layer including an oxide layer and a second protective layer including a nitride layer, sequentially stacked. The first protective layer may include silicon oxide, and the second protective layer may include silicon nitride or silicon carbonitride.

The first bonding pad 13 may be provided in the first passivation layer 124. The first bonding pad 13 may be exposed through an outer surface of the first passivation layer 124. In some implementations, an insulation interlayer may be provided on the first surface 112 of the substrate 11 to cover the circuit patterns. The insulation interlayer may be formed to include, for example, silicon oxide or a low dielectric material. The insulation interlayer may include lower wiring therein, which are electrically connected to the circuit patterns. Accordingly, the circuit pattern may be electrically connected to the first bonding pad 13 by the lower wirings and the wirings.

The through electrode (through silicon via, TSV) 14 may vertically penetrate the insulation interlayer and extend from the first surface 112 to the second surface 114 of the substrate 11. The through electrode 14 may contact a lowermost wiring of the metal wiring structure. Accordingly, the through electrode 24 may be electrically connected to the first bonding pad 13 by the wirings 123.

The backside insulating layer 16 may be formed on the second surface 114 of the substrate 11, e.g., the backside surface. The second bonding pad 17 may be provided in the backside insulating layer 16. For example, the second bonding pad 17 may be disposed on an exposed surface of the through electrode 14. The backside insulating layer 16 may include silicon oxide, carbon-doped silicon oxide, silicon carbonitride (SiCN), and other suitable/desired materials. Accordingly, the first and second bonding pads 13 and 17 may be electrically connected to each other by the through electrode 24.

In some implementations, each of the first to fourth core die stack DS1, DS2, DS3, and DS4 may include at least one intermediate core, e.g., second semiconductor chip 20, and a gap filling portion 30 that covers an outer surface of the at least one intermediate core, e.g., second semiconductor chip 20. The at least one intermediate core, e.g., second semiconductor chip 20, may include a substrate 21, a front insulating layer 22 provided on a front surface of the substrate 21 and in which a first bonding pad 23 is provided, and a backside insulating layer 26 provided on a backside surface of the substrate 21 and in which a second bonding pad 27 is provided. In addition, the at least one intermediate core, e.g., second semiconductor chip 20, may further include a through electrode 24 that penetrates the substrate 21 and is electrically connected to the first and second bonding pads 23 and 27.

In particular, the first core die stack DS1 may be bonded onto the buffer die 10. The first core die stack DS1 may include first intermediate cores 20a and 20b stacked in two stages and a first gap filling portion 30-1 covering outer surfaces of the first intermediate cores 20a and 20b.

As illustrated in FIGS. 2 and 3, the first-stage first intermediate core 20a of the first core die stack DS1 may include a substrate 21a, a front insulating layer 22a, and a plurality of first bonding pads 23a, a plurality of through electrodes 24a, a backside insulating layer 26a and a plurality of second bonding pads 27a.

The substrate 21a may have a first surface 212a and a second surface 214a opposite to the first surface 212a. The first surface 212a may be an active surface, and the second surface 214a may be a non-active side. Circuit patterns may be provided on the first surface 212a of the substrate 21a. The front insulating layer 22a as an insulation interlayer may be formed on the first surface 212a of the substrate 21a, e.g., a front surface. The front insulating layer 22a may include a plurality of insulating layers 222a and 224a and wirings 223a in the insulating layers 222 and 224. Additionally, the first bonding pad 23a may be provided in an outermost insulating layer of the front insulating layer 22a. For example, the front insulating layer 22a may include a metal wiring layer 222a and a first passivation layer 224a. The metal wiring layer 222a may include a plurality of wirings 223a therein.

The through electrode 24a may vertically extend from the first surface 212a to the second surface 214a of the substrate 21a. The through electrode 24a may be electrically connected to the first bonding pad 23a by the wirings 223a. The backside insulating layer 26a may be formed on the second surface 214a of the substrate 21a, e.g., a backside surface. The second bonding pad 27a may be provided in the backside insulating layer 26a. Accordingly, the first and second bonding pads 23a and 27a may be electrically connected to each other by the through electrode 24a.

Similarly, the second-stage first intermediate core 20b of the first core die stack DS1 may include a substrate 21b, a front insulating layer 22b, a plurality of first bonding pads 23b, a plurality of through electrodes 24b, a backside insulating layer 26b, and a plurality of second bonding pads 27b. Since the cores 20a, 20b, 20c, 20d, 20e, 20f, 20g, and 20h are substantially the same as or similar to each other, same or like reference numerals will be used to refer to the same or like elements and repeated descriptions of the same elements may be omitted.

As illustrated in FIG. 2, the first-stage first intermediate core 20a and the buffer die 10 may be bonded to each other by hybrid bonding. The second bonding pad 17 of the buffer die 10 and the first bonding pad 23a of the first intermediate core 20a may be bonded to each other by copper-copper hybrid bonding (Cu—Cu Hybrid Bonding). The front surface of the first intermediate core 20a, e.g., the front side insulating layer 22a on the first surface 212a of the substrate 21a may be directly bonded to the backside insulating layer 16 of the substrate 11 of the buffer die 10.

As illustrated in FIG. 3, the second-stage first intermediate core 20b and the first-stage first intermediate core 20a may be bonded to each other by hybrid bonding. The second bonding pad 27a of the first-stage first intermediate core 20a and the first bonding pad 23b of the second-stage first intermediate core 20b may be bonded to each other by copper-copper hybrid bonding (Cu—Cu Hybrid Bonding).

The front insulating layer 22b on the front surface of the second-stage first intermediate core die 20b may be directly bonded to the backside insulating layer 26a on the backside surface of the first-stage first intermediate core die 20a. The outermost insulating layers of the backside insulating layer 26a and the front insulating layer 22b may include an insulating material that contacts each other and provides excellent bonding strength, thereby providing a bonding structure. The backside insulating layer 26a and the front insulating layer 22b may be bonded to each other by a high temperature annealing process while in contact with each other. Here, the bonding structure may have a relatively stronger bonding strength due to covalent bonding.

The first gap filling portion 30-1 may be provided to cover the outer surfaces of the first intermediate cores 20a and 20b stacked in two stages on the buffer die 10. For example, the first gap filling portion 30-1 may be formed by a conformal deposition process such as an atomic layer deposition (ALD) process or a chemical vapor deposition (CVD) process. The first gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like.

In some implementations, the second core die stack DS2 may be bonded onto the first core die stack DS1. The second core die stack DS2 may include second intermediate cores 20c, 20d stacked in two stages and a second gap filling portion 30-2 covering outer surfaces of the second intermediate cores 20c and 20d.

The second-stage second intermediate core 20d and the first-stage second intermediate core 20c may be bonded to each other by hybrid bonding. A second bonding pad 27c of the first-stage second intermediate core 20c and a first bonding pad 23d of the second-stage second intermediate core 20d may be bonded to each other by copper-copper hybrid bonding. A front side insulating layer 22d on a front surface of the second-stage intermediate core 20d may be directly bonded to a backside insulating layer 26c on a backside surface of the first-stage second intermediate core 20c.

The first-stage second intermediate core 20c of the second core die stack DS2 and the second-stage first intermediate core 20b of the first core die stack DS1 may be bonded to each other by hybrid bonding. The second bonding pad 27b of the first intermediate core 20b and a first bonding pad 23c of the second intermediate core 20c may be bonded to each other by copper-copper hybrid bonding. A front insulating layer 22c on a front surface of the second intermediate core 20c may be directly bonded to the backside insulating layer 26b on the backside surface of the first intermediate core 20b.

The second gap filling portion 30-2 may be provided to cover the outer surfaces of the second intermediate cores 20c and 20d stacked in two stages. For example, the second gap filling portion 30-2 may be formed by a conformal deposition process such as an atomic layer deposition (ALD) process or a chemical vapor deposition (CVD) process. The second gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like.

As illustrated in FIG. 4, when the second core die stack DS2 and the first core die stack DS1 are bonded to each other, the second gap filling portion 30-2 of the second core die stack DS2 and the first gap filling portion 30-1 of the first core die stack DS1 may be bonded to each other by a thermal compression process and an annealing process. By the annealing process, the first gap filling portion 30-1 and the second gap filling portion 30-2 may be directly bonded to each other to form a bonding interface layer. The bonding interface layer may have a thickness in a range of 2 Å to 500 Å. The bonding interface layer may include silicon oxide. The bonding interface layer may be detected by a transmission electron microscope (TEM).

In some implementations, the third core die stack DS3 may be bonded onto the second core die stack DS2. The third core die stack DS3 may include third intermediate cores 20e and 20f stacked in two stages and a third gap filling portion 30-3 covering outer surfaces of the third intermediate cores 20e and 20f.

The second-stage third intermediate core 20f and the first-stage third intermediate core 20e may be bonded to each other by hybrid bonding. The first-stage third intermediate core 20e of the third core die stack DS3 and the second-stage second intermediate core 20d of the second core die stack DS2 may be bonded to each other by hybrid bonding.

The third gap filling portion 30-3 may be provided to cover the outer surfaces of the third intermediate cores 20e and 20f stacked in two stages. For example, the third gap filling portion may include an inorganic dielectric layer or an organic dielectric layer.

When the third core die stack DS3 and the second core die stack DS2 are bonded to each other, the third gap filling portion 30-3 of the third core die stack DS3 and the second gap filling portion 30-2 of the second core die stack DS2 may be bonded to each other by a thermal compression process and an annealing process. By the annealing process, the second gap filling portion 30-2 and the third gap filling portion 30-3 may be directly bonded to each other to form a bonding interface layer. The bonding interface layer may include silicon oxide.

In some implementations, the fourth core die stack DS4 may be bonded onto the third core die stack DS2. The fourth core die stack DS4 may include a fourth intermediate core 20g stacked in one stage and a fourth gap filling portion 30-4 covering an outer surface of the fourth intermediate core 20g.

The fourth intermediate core 20g of the fourth core die stack DS4 and the third intermediate core 20f of the third core die stack DS3 may be bonded to each other by hybrid bonding. The fourth gap filling portion 30-4 may be provided to cover the outer surface of the fourth intermediate core 20g. For example, the fourth gap filling portion may include an inorganic dielectric layer or an organic dielectric layer.

When the fourth core die stack DS4 and the third core die stack DS3 are bonded to each other, the fourth gap filling portion 30-4 of the fourth core die stack DS4 and the third gap filling portion 30-3 of the third core die stack DS3 may be bonded to each other by a thermal compression process and an annealing process. By the annealing process, the third gap filling portion 30-3 and the fourth gap filling portion 30-4 may be directly bonded to each other to form a bonding interface layer. The bonding interface layer may include silicon oxide.

In some implementations, the top core die stack DS5 may be bonded onto the fourth core die stack DS4. The top core die stack DS5 may include a top core 20h stacked in one stage and a fifth gap filling portion covering an outer surface of the top core 20h. A thickness of the top core 20h may be greater than thicknesses of the intermediate cores 20a, 20b, 20c, 20d, 20e, 20f, and 20g. The thickness of the top core 20h may be in a range of 100 μm to 300 μm. The thicknesses of the intermediate core dies 20a, 20b, 20c, 20d, 20e, 20f, and 20g may be in a range of 20 μm to 50 μm.

The top core 20h of the top core die stack DS5 and the fourth intermediate core 20h of the fourth core die stack DS4 may be bonded to each other by hybrid bonding. The fifth gap filling portion 30-5 may be provided to cover the outer surface of the top core 20h. For example, the fifth gap filling portion 30-5 may include an inorganic dielectric layer or an organic dielectric layer.

When the top core die stack DS5 and the fourth core die stack DS4 are bonded to each other, the fifth gap filling portion 30-5 of the top core die stack DS5 and the fourth gap filling portion 30-4 of the fourth core die stack DS4 may be bonded to each other by a thermal compression process and an annealing process. By the annealing process, the fourth gap filling portion 30-4 and the fifth gap filling portion 30-5 may be directly bonded to each other to form a bonding interface layer. The bonding interface layer may include silicon oxide.

In some implementations, a width of buffer die 10 may be the same as widths of the first to fourth core die stacks DS1, DS2, DS3, and DS4. The widths of the first to fourth core die stacks DS1, DS2, DS3, and DS4 may be the same as a width of the top core die stack DS5. The width of the buffer die 10 may be the same as the width of the top core die stack DS5.

An outer surface of the buffer die 10 and outer surfaces of the first to fourth core die stacks DS1, DS2, DS3, and DS4 may be positioned on the same plane. An outer surface of the substrate 11 of the buffer die 10 may be coplanar with outer surfaces of the first to fourth gap filling portions 30-1, 30-2, 30-3, and 30-4 of the first to fourth core die stacks DS1, DS2, DS3, and DS4.

The outer surfaces of the first to fourth core die stacks DS1, DS2, DS3, and DS4 and the outer surface of the top core die stack DS5 may be positioned on the same plane. The outer surfaces of the first to fourth gap filling portions 30-1, 30-2, 30-3, and 30-4 of the first to fourth core die stacks DS1, DS2, DS3, and DS4 may be coplanar with an outer surface of the fifth gap filling portion 30-5 of the top core die stack DS5.

As mentioned above, the semiconductor package 100 may include the first to fourth core die stacks DS1, DS2, DS3, and DS4 and the top core die stack DS5 sequentially stacked on the buffer die 10. Each of the first to fourth core die stacks DS1, DS2, DS3 and DS4 may include the at least one intermediate core 20a and the gap filling portion 30 covering the outer surface of the at least one intermediate core, e.g., second semiconductor chip 20.

The first to fourth core die stacks DS1, DS2, DS3, and DS4 may be bonded to each other by hybrid bonding. The gap filling portions 30-1, 30-2, 30-3, and 30-4 of the first to fourth core die stacks DS1, DS2, DS3, and DS4 may be directly bonded to each other. The gap filling portions may include an inorganic dielectric layer or an organic dielectric layer. The gap filling portions may be directly bonded to each other to form the bonding interface layer 32.

The first to fourth core die stacks DS1, DS2, DS3, and DS4 may be bonded to each other. Each time each of the first to fourth core die stacks DS1, DS2, DS3, and DS4 is stacked, the upper surfaces of the uppermost intermediate cores may be planarized to initialize topology due to the stacking of the intermediate cores.

Accordingly, it may be possible to prevent voids from occurring at the bonding interface due to accumulation of bonding interface topology during high-level chip stacking. Thus, by using the wafer-to-wafer bonding method, costs due to an increase in the topology initialization process using a wafer support system WSS may be reduced.

Hereinafter, a method of manufacturing the semiconductor package of FIG. 1 will be described. A case where the semiconductor package includes a high bandwidth memory (HBM) device will be described. However, it will be understood that a method of manufacturing a semiconductor package is not limited thereto.

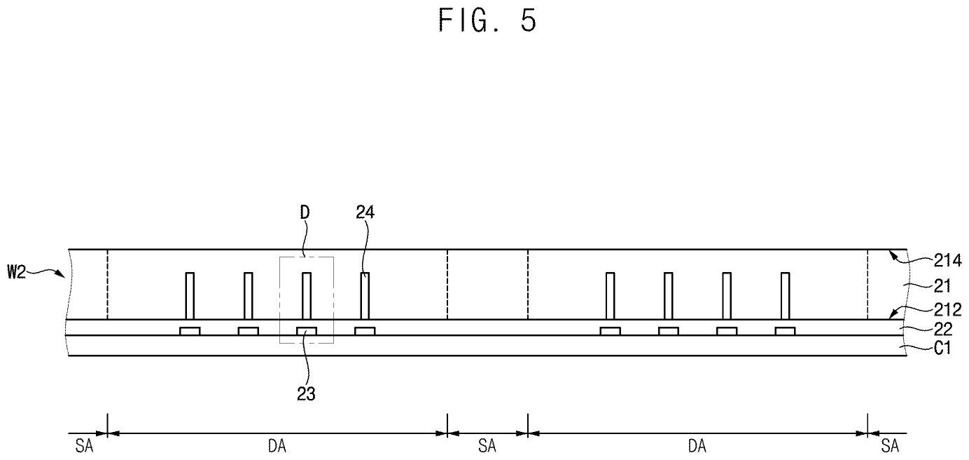

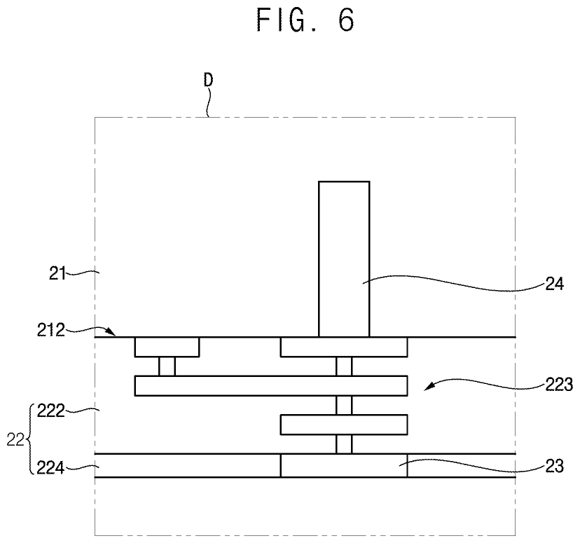

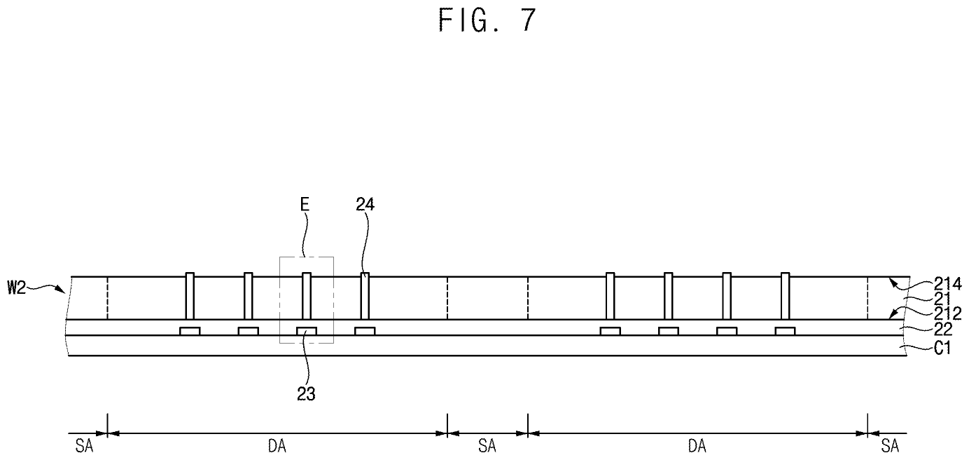

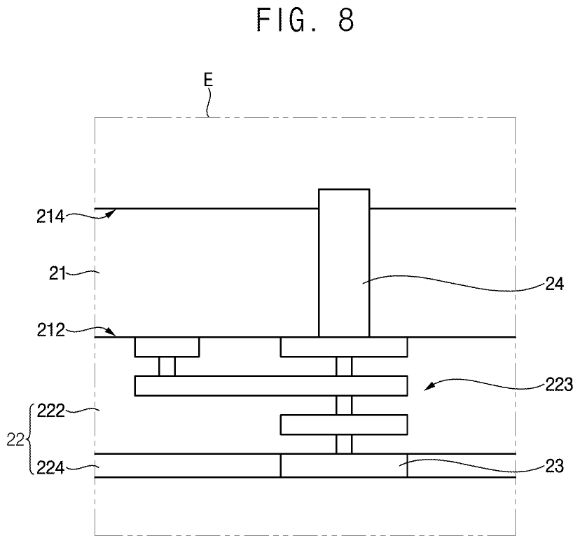

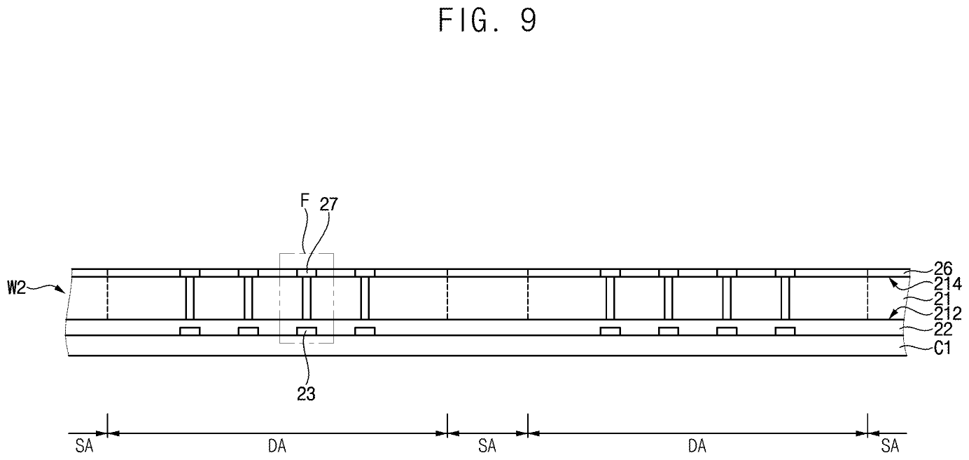

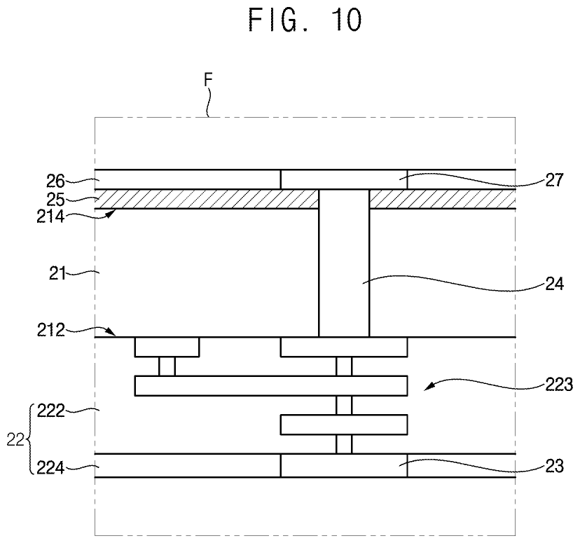

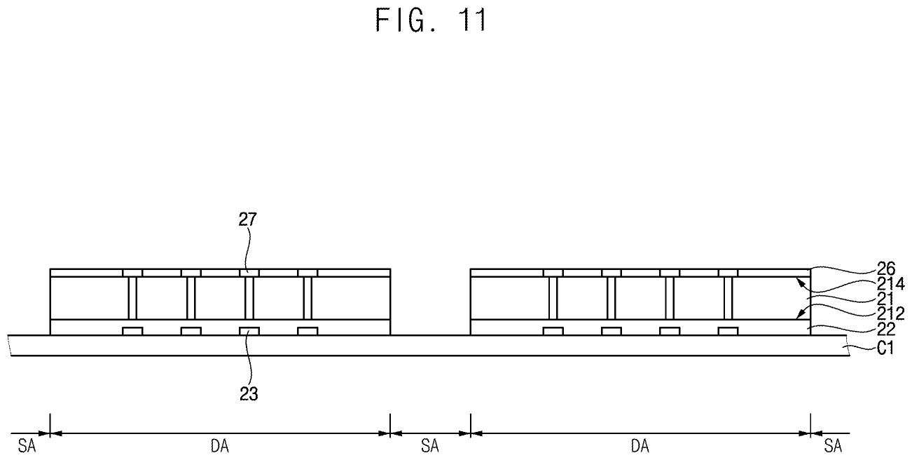

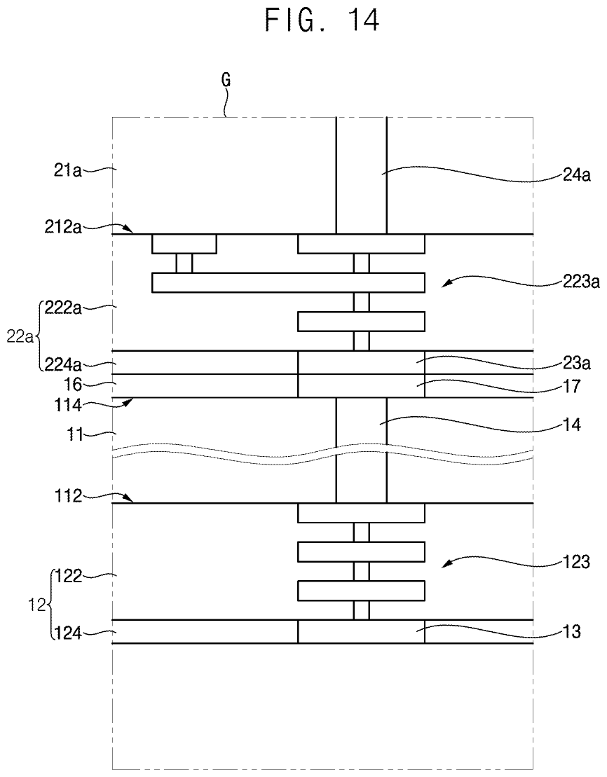

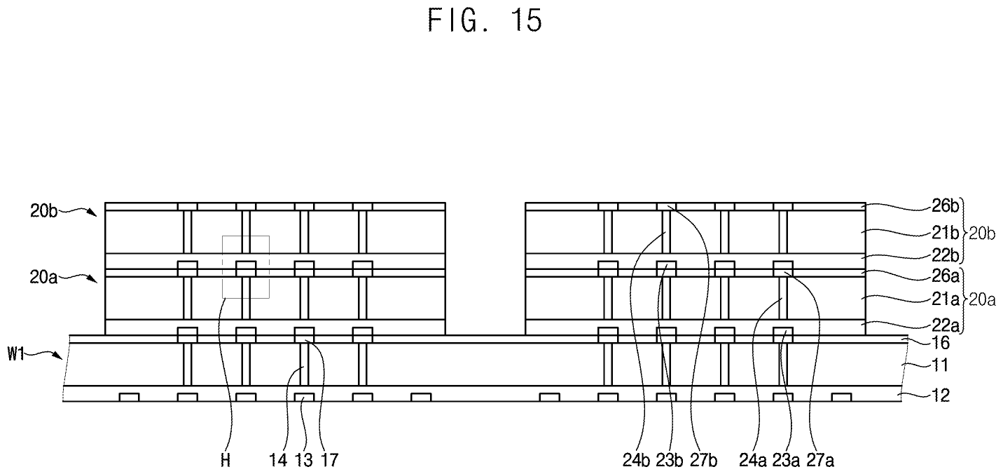

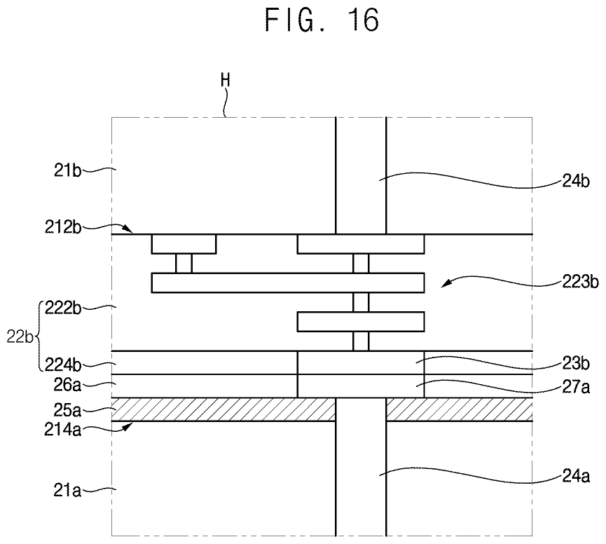

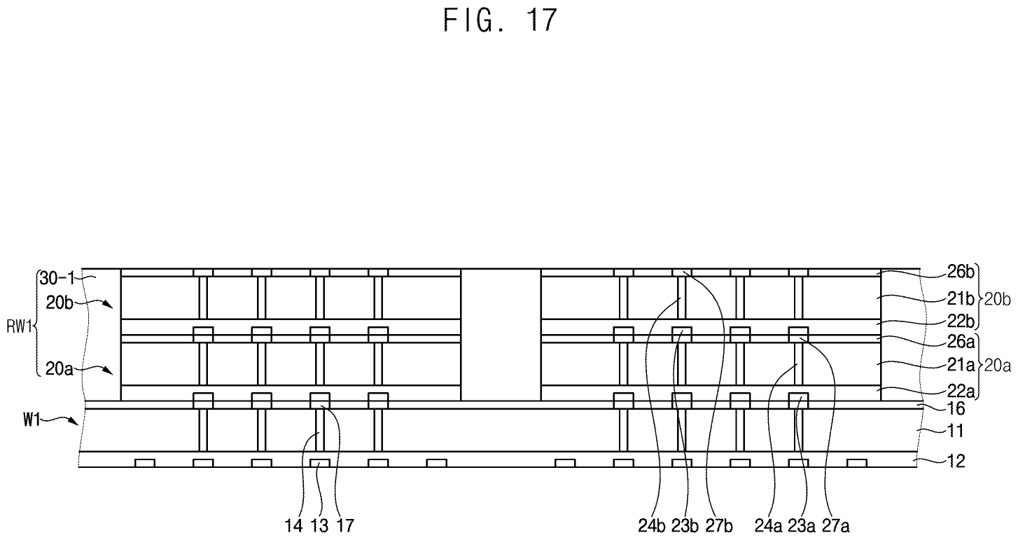

FIGS. 5 to 28 are views illustrating an example of a method of manufacturing a semiconductor package. FIG. 6 is an enlarged cross-sectional view illustrating portion ‘D’ in FIG. 5. FIG. 8 is an enlarged cross-sectional view illustrating portion ‘E’ in FIG. 7. FIG. 10 is an enlarged cross-sectional view illustrating portion ‘F’ in FIG. 9. FIG. 14 is an enlarged cross-sectional view illustrating portion ‘G’ in FIG. 13. FIG. 16 is an enlarged cross-sectional view illustrating portion ‘H’ in FIG. 15.

Referring to FIGS. 5 to 12, first, a second wafer W2 may be individualized into semiconductor chips (core dies) 20.

As illustrated in FIGS. 5 and 6, the second wafer W2 including a plurality of semiconductor chips (core dies) formed therein may be prepared.

In some implementations, the second wafer W2 may include a substrate 21 and a front insulating layer 22 having a first bonding pad 23 that is provided in an outer surface thereof. Additionally, the second wafer W2 may include a plurality of through electrodes 24 that are provided in the substrate 21 and are electrically connected to the first bonding pads 23.

The substrate 21 may have a first surface 212 and a second surface 214 opposite to each other. The substrate 21 may include a die region DA where circuit patterns and cells are formed and a scribe lane region SA surrounding the die region DA. The substrate 21 may be cut along the scribe lane region SA that divides the plurality of die regions DA of the second wafer W2 by a following dicing process to form individualized semiconductor chips.

For example, the substrate 21 may include silicon, germanium, silicon-germanium, or III-V compounds, e.g., GaP, GaAs, GaSb, and other suitable/desired materials. In some implementations, the second substrate 21 may be a silicon-on-insulator (SOI) substrate, or a germanium-on-insulator (GOI) substrate.

The circuit patterns may include transistors, capacitors, diodes, and other suitable/desired electronic components. The circuit patterns may constitute circuit elements. Accordingly, the semiconductor chip may be a semiconductor device with a plurality of the circuit elements formed therein. The circuit patterns may be formed on the first surface 212 of the substrate 21 by performing a FEOL (Front End of Line) process for manufacturing semiconductor devices. The surface of the substrate on which the FEOL process is performed may be referred to as a front surface of the substrate, and a surface opposite to the front surface may be referred to as a backside surface.

The circuit element may include a plurality of memory devices. Examples of the memory devices include a volatile semiconductor memory device and a non-volatile semiconductor memory device. Examples of the volatile semiconductor memory device may be DRAM, SRAM, and other types of memory devices. Examples of the non-volatile semiconductor memory devices may be EPROM, EEPROM, Flash EEPROM, and other types of memory devices.

The front insulating layer 22 may be formed as an insulation interlayer on the first surface 212 of the substrate 21, e.g., the front surface. The front insulating layer 22 may include a plurality of insulating layers 122 and 124 and wirings 223 in the insulating layers. Additionally, the first bonding pad 23 may be provided in the outermost insulating layer of the front insulating layer 22.

As illustrated in FIG. 6, for example, the front insulating layer 22 may include a metal wiring layer 222 and a first passivation layer 224.

The metal wiring layer 222 may include the plurality of wirings 223 therein. For example, the metal wiring layer 222 may include a metal wiring structure including the plurality of wirings 223 vertically stacked in buffer layers and insulating layers. The first bonding pad 23 may be formed on an uppermost wiring among the plurality of wirings 223. For example, the wirings may include aluminum (Al), copper (Cu), tin (Sn), nickel (Ni), gold (Au), platinum (Pt), or alloys thereof.

The first passivation layer 224 may be formed on the metal wiring layer 222 and may expose at least a portion of the first bonding pad 23. The first passivation layer 224 may include a plurality of stacked insulating layers. For example, the first passivation layer 224 may include a first protective layer including an oxide layer and a second protective layer including a nitride layer, sequentially stacked. The first protective layer may include silicon oxide, and the second protective layer may include silicon nitride or silicon carbonitride.

The first bonding pad 23 may be provided in the first passivation layer 224. The first bonding pad 23 may be exposed from an outer surface of the first passivation layer 224. In some implementations, an insulation interlayer may be provided on the first surface 212 of the substrate 21 to cover the circuit patterns. The insulation interlayer may be formed to include, for example, silicon oxide or a low dielectric material. The insulation interlayer may include lower wirings therein, which are electrically connected to the circuit patterns. Accordingly, the circuit pattern may be electrically connected to the first bonding pad 23 by the lower wirings and the wirings.

The through electrode (through silicon via, TSV) 24 may vertically penetrate the insulation interlayer and extend from the first surface 212 of the substrate 21 to a predetermined depth. The through electrode 24 may contact a lowermost wiring of the metal wiring structure. Accordingly, the through electrode 24 may be electrically connected to the first bonding pad 23 by the wirings 223.

In some implementations, a liner layer may be provided on an outer surface of the through electrode 24. The liner layer may include silicon oxide or carbon-doped silicon oxide. The liner layer may electrically insulate the through electrode 24 from the substrate 21 and the metal wiring layer 222.

The through electrode 24 and the first bonding pad 23 may include a same metal. For example, the metal may include copper (Cu). However, it is not limited thereto, and the through electrode and the first bonding pad may include a material (e.g., gold (Au)) that can be bonded by inter-diffusion of metals by a high-temperature annealing process.

As illustrated in FIGS. 7 and 8, the second surface 214 of the substrate 21 may be partially removed to expose one end portion of the through electrode 24.

In some implementations, the second surface 214 of the substrate 21 may be partially removed using a substrate support system (WSS). First, the second wafer (W2) may be attached to a carrier substrate C1 using an adhesive film, and then, the second surface 214 of the substrate 21 may be partially removed until the end portion of the through electrode 24 is exposed.

In particular, a grinding process such as a back lap process may be performed to partially remove the second surface 214 of the substrate 21, and then an etching process such as a silicon recess process may be performed to expose the end portion of the through electrode 24. Accordingly, a thickness of the substrate 21 may be reduced to a desired thickness. For example, the substrate 21 may have the thickness in a range of about 20 μm to about 50 μm.

In the back lap process, the entire backside surface of the second wafer W2 may be grinded. In the silicon recess process, only the silicon in the backside surface of the second wafer W2 may be selectively etched. The etching process may be an isotropic dry etching process. The etching process may include a plasma etching process or a similar method. The plasma etching process may be performed using inductively coupled plasma, capacitively coupled plasma, microwave plasma, and other types of plasma.

Since the grinding process and the etching process are performed in the wafer level, the entire second surface 214 of the substrate 21 may be reduced to a uniform thickness. Accordingly, the end portions of the through electrodes 24 may protrude uniformly from the second surface 214 of the substrate 21 across the entire second surface 214 of the substrate 21 to have same heights.

As illustrated in FIGS. 9 and 10, a backside insulating layer 26 having a second bonding pad 27 in an outer surface thereof may be formed on the second surface 214 of the substrate 21.

For example, an etch stop layer may be formed on the second surface 214 of the substrate 21, and a sacrificial layer may be formed on the etch stop layer. The etch stop layer may be conformally formed to cover the end portions of the through electrodes 24 that protrude from the second surface 214 of the substrate 21. The etch stop layer may cover the entire second surface 214 of the substrate 21. For example, the etch stop layer may have a thickness within a range of 0.1 μm to 1 μm. The etch stop layer may include a material that can be used to detect a polishing end point in a subsequent chemical mechanical polishing process. The etch stop layer may include a silicon nitride layer. The thickness and material of the etch stop layer may be selected in consideration of a polishing selectivity and polishing conditions in the subsequent chemical mechanical polishing process.

The sacrificial layer may be formed on the etch stop layer to fill a gap between the protruding end portions of the through electrodes 24. The sacrificial layer may include silicon oxide such as tetraethyl orthosilicate (TEOS).

Then, a chemical mechanical polishing (CMP) process may be performed to remove the sacrificial layer to expose the end portions of the through electrodes 24. In the chemical mechanical polishing (CMP) process, the etch stop layer may be used to detect a polishing end point. Through the CMP process, the end portions of the through electrodes 24 and portions of the etch stop layer covering the end portions of the through electrodes 24 may be removed to form an etch stop layer pattern 25 on the second surface 214 of the substrate 21.

The etch stop layer pattern 25 may expose the end portions of the through electrodes 24. The end portions of the through electrodes 24 may protrude from the second surface 214 of the substrate 21, and the etch stop layer pattern 25 may cover sidewalls of the end portions of the through electrodes that protrude from the second surface 214 of the substrate 210. Accordingly, upper surfaces of the through electrodes 24 may be exposed by the etch stop layer pattern 25. An upper surface of the etch stop layer pattern 25 and the exposed upper surfaces of the through electrodes 24 may be positioned on the same plane.

Then, the backside insulating layer 26 as a second passivation layer may be formed on the etch stop layer pattern 25 on the second surface 214 of the substrate 21. The backside insulating layer 26 may have the second bonding pad 27 that is electrically connected to the through electrode 24.

For example, after the backside insulating layer 26 is formed on the etch stop layer pattern 25 on the second surface 214 of the substrate 21, an opening may be formed in the backside insulating layer 26 to expose the through electrode 24, and a plating process may be performed to form the second bonding pad 27 in the opening of the backside insulating layer 26. The second bonding pad 27 may be disposed on the exposed surface of the through electrode 24. The backside insulating layer 26 may include silicon oxide, carbon-doped silicon oxide, silicon carbonitride (SiCN), and other suitable/desired materials. Accordingly, the first and second bonding pads 23 and 27 may be electrically connected to each other by the through electrode 24.

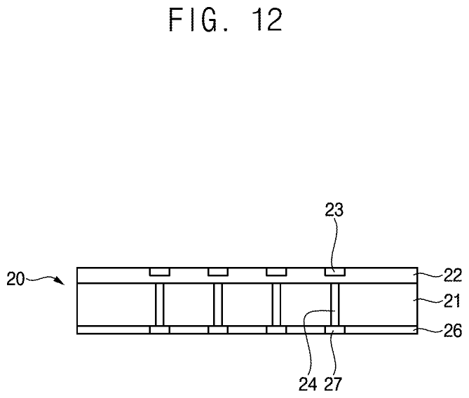

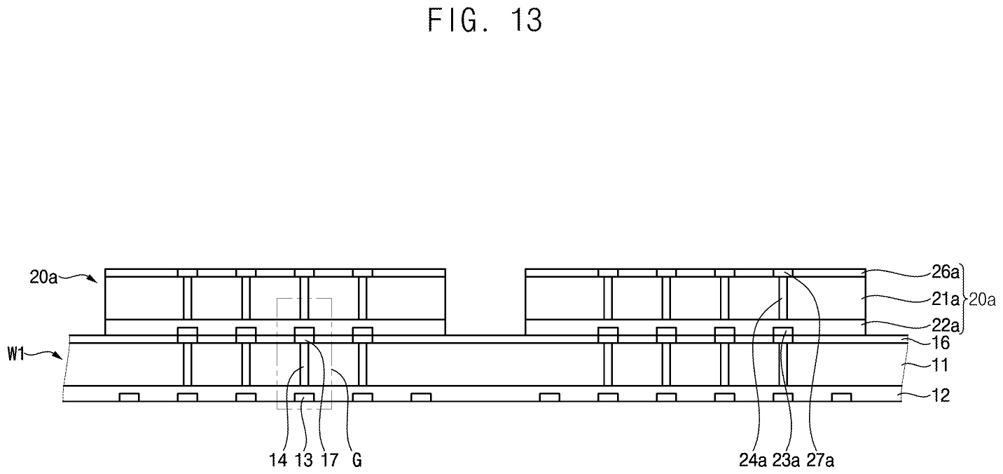

Referring to FIGS. 11 and 12, the second wafer W2 may be cut along the scribe lane region SA to form individual second semiconductor chips (core dies) 20. The individual second semiconductor chip 20 may be separated from the carrier substrate C1.

Referring to FIGS. 13 to 17, a first reconstructed wafer RW1 including at least one first intermediate core 20a and 20b and a first gap filling portion 30-1 covering an outer surface of the at least one first intermediate core 20a and 20b may be formed on a first wafer W1. In this example, the first reconstructed wafer RW1 may include, but is not limited to, the first intermediate cores 20a and 20b stacked in two stages.

As illustrated in FIGS. 13 and 14, a plurality of the first intermediate cores 20a may be attached in a first stage on the first wafer W1 (die-to-wafer hybrid bonding process).

In some implementations, the first intermediate cores 20a may be disposed on the first wafer W1 to correspond to die region DA. The first intermediate core 20a may be stacked such that a first surface 212a of a substrate 21a faces the first wafer W1.

A die bonding apparatus may pick up the first intermediate core 20a separated by a sawing process and may bond the first intermediate core 20a to the first wafer W1. The die bonding apparatus may attach the first intermediate core 20a to the first wafer W1 by performing a thermal compression process at a predetermined temperature (for example, about 400° C. or less). By the thermal compression process, the first intermediate core 20a and the first wafer W1 may be bonded to each other through hybrid bonding. That is, a front surface of the first intermediate core 20a, e.g., a front side insulating layer 22a on the first surface 212a of the substrate 21a may be directly bonded to a backside insulating layer 16 on a substrate 11 of the first wafer W1.

A second bonding pad 17 of the first wafer W1 and a first bonding pad 23a of the first intermediate core 20a may make contact with each other. The front surface of the first intermediate core 20a and a backside surface of the first wafer W1 may be bonded to face each other. When the first wafer W1 and the first intermediate core 20a are bonded to each other by wafer-to-die bonding, the second bonding pad 17 of the first wafer W1 and the first bonding pads 23a of the first intermediate core 20a may be bonded to each other by copper-copper hybrid bonding (Cu—Cu Hybrid Bonding).

As illustrated in FIGS. 15 and 16, processes the same as or similar to the processes described with reference to FIGS. 13 and 14 may be performed to attach a plurality of first intermediate cores 20b in a second stage on the plurality of first-stage first intermediate cores 20a on the first wafer W1 (die-to-wafer hybrid bonding process).

A front surface of the second-stage first intermediate core 20b may be stacked to face the backside surface of the first-stage first intermediate core 20a. By a thermal compression process, the second-stage first intermediate core 20b and the first-stage first intermediate core 20a may be bonded to each other through hybrid bonding. That is, a front insulating layer 22b on the front surface of the second-stage first intermediate core 20b may be directly bonded to a backside insulating layer 26a on the backside surface of the first-stage first intermediate core 20a. When the first-stage first intermediate core 20a and the second-stage first intermediate core 20b are bonded to each other by die-to-die bonding, a second bonding pad 27a of the first-stage first intermediate core 20a and a first bonding pad 23b of the second-stage first intermediate core 20b may be bonded to each other by copper-copper hybrid bonding.

As illustrated in FIG. 17, the first gap filling portion 30-1 may be formed to fill gaps between the first intermediate cores 20a and 20b stacked in two stages on the first wafer W1.

A filling layer may be formed to cover the first intermediate cores 20a and 20b stacked in two stages on the first wafer W1, and an upper portion of the filling layer may be removed to form the first gap filling portion 30-1 that exposes upper surfaces of the second-stage first intermediate cores 20b. For example, the first gap filling portion 30-1 may be formed by a conformal deposition process such as an atomic layer deposition (ALD) process or a chemical vapor deposition (CVD) process. The first gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like. The upper portion of the filling layer may be removed by a chemical mechanical polishing process or a mechanical grinding process.

Then, an upper surface of the first reconstructed wafer RW1, e.g., the upper surfaces of the second-stage first intermediate cores 20b, may be planarized to initialize a topology due to the stacking of the first intermediate cores 20a and 20b. For example, a chemical mechanical polishing (CMP) process may be performed to remove topology accumulation in bonding interfaces of the second-stage first intermediate cores 20b (topology reset process).

Accordingly, the first reconstructed wafer RW1 including the first intermediate cores 20a and 20b stacked in two stages and the first gap filling portion 30-1 covering the outer surfaces of the first intermediate cores 20a and 20b may be formed.

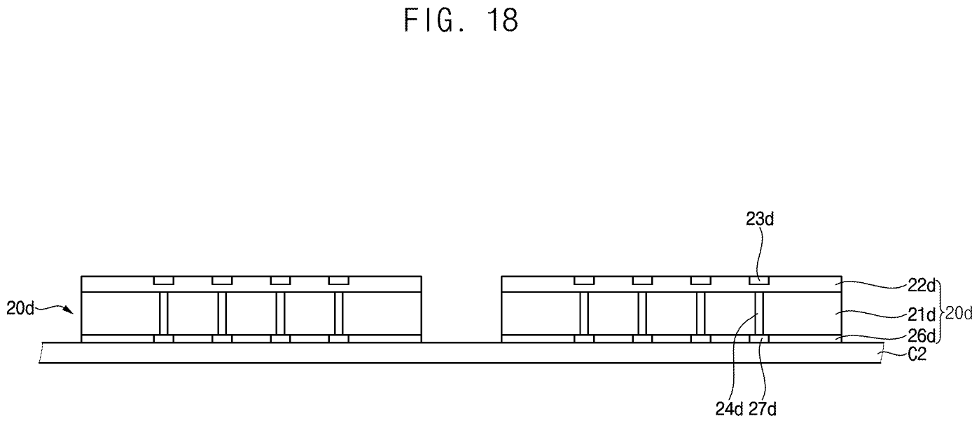

Referring to FIGS. 18 to 20, a second reconstructed wafer RW2 including at least one second intermediate core 20c and 20d and a second gap filling portion 30-2 covering an outer surface of the at least one second intermediate core 20c and 20d may be formed on a carrier substrate C2. In this example, the second reconstructed wafer RW2 may include, but is not limited to, the second intermediate cores 20c and 20d stacked in two stages.

As illustrated in FIG. 18, a plurality of the second intermediate cores 20d may be attached in a first stage on the carrier substrate C2.

In some implementations, the second intermediate cores 20d may be disposed on the carrier substrate C2 to correspond to die region DA. The second intermediate cores 20d may be attached to the carrier substrate C2 using an adhesive film or an oxide layer. The second intermediate core 20d may be stacked such that a second surface 214d of a substrate 21d faces the carrier substrate C2.

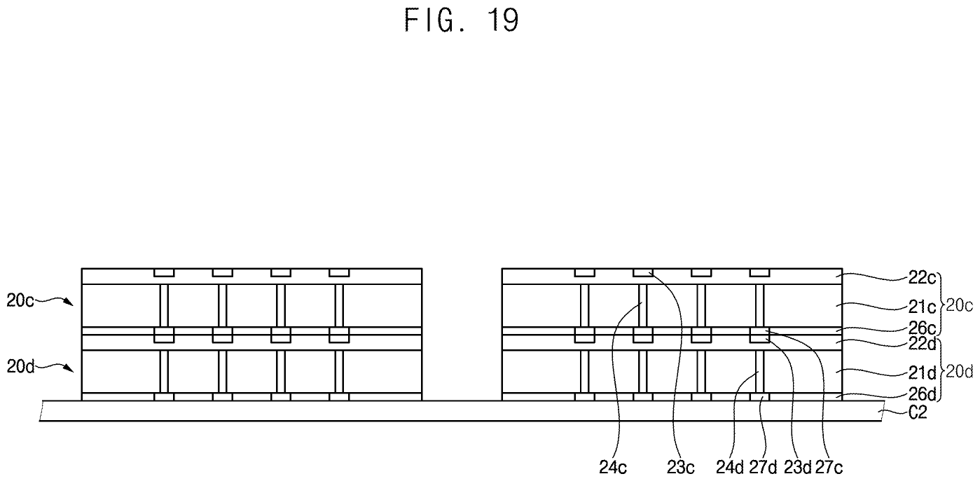

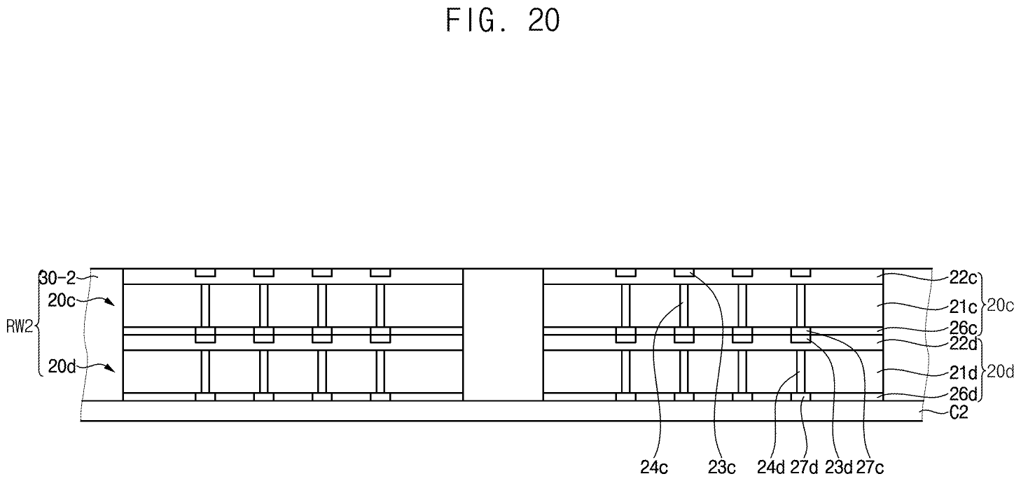

As illustrated in FIG. 19, processes the same as or similar to the processes described with reference to FIGS. 13 and 14 may be performed to attach a plurality of second intermediate cores 20c in a second stage on the plurality of first-stage second intermediate cores 20d on the carrier substrate C2 (die-to-wafer hybrid bonding process).

A backside surface of the second-stage second intermediate core 20c may be stacked to face a front surface of the first-stage second intermediate core 20c. By a thermal compression process, the second-stage second intermediate core 20c and the first-stage second intermediate core 20d may be bonded to each other through hybrid bonding. That is, a backside insulating layer 26c on the backside surface of the second-stage second intermediate core 20c may be directly bonded to a front side insulating layer 22d on the front surface of the first-stage second intermediate core 20d. When the first-stage second intermediate core 20d and the second-stage second intermediate core 20c are bonded to each other by die-to-die bonding, a first bonding pad 23d of the first-stage second intermediate core 20d and a second bonding pad 27d of the second-stage second intermediate core 20c may be bonded to each other by copper-copper hybrid bonding.

As illustrated in FIG. 20, processes the same as or similar to the processes described with reference to FIG. 17 may be performed to form the second gap filling portion 30-2 that fills gaps between the second intermediate cores 20c and 20d stacked in two stages on the carrier substrate C2.

A filling layer may be formed to cover the second intermediate cores 20c and 20d stacked in two stages on the carrier substrate C2, and an upper portion of the filling layer may be removed to form the second gap filling portion 30-2 that exposes upper surfaces of the second-stage second intermediate cores 20c. For example, the second gap filling portion 30-2 may be formed by a conformal deposition process such as an atomic layer deposition (ALD) process or a chemical vapor deposition (CVD) process. The second gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like. The upper portion of the filling layer may be removed by a chemical mechanical polishing process or a mechanical grinding process.

Then, an upper surface of the second reconstructed wafer RW2, e.g., the upper surfaces of the second-stage second intermediate cores 20c, may be planarized to initialize a topology due to the stacking of the second intermediate cores 20c and 20d. For example, a chemical mechanical polishing (CMP) process may be performed to remove topology accumulation in bonding interfaces of the second-stage second intermediate cores 20c (topology reset process).

Accordingly, the second reconstructed wafer RW2 including the second intermediate cores 20c and 20d stacked in two stages and the second gap filling portion 30-2 covering the outer surfaces of the second intermediate cores 20c and 20d may be formed.

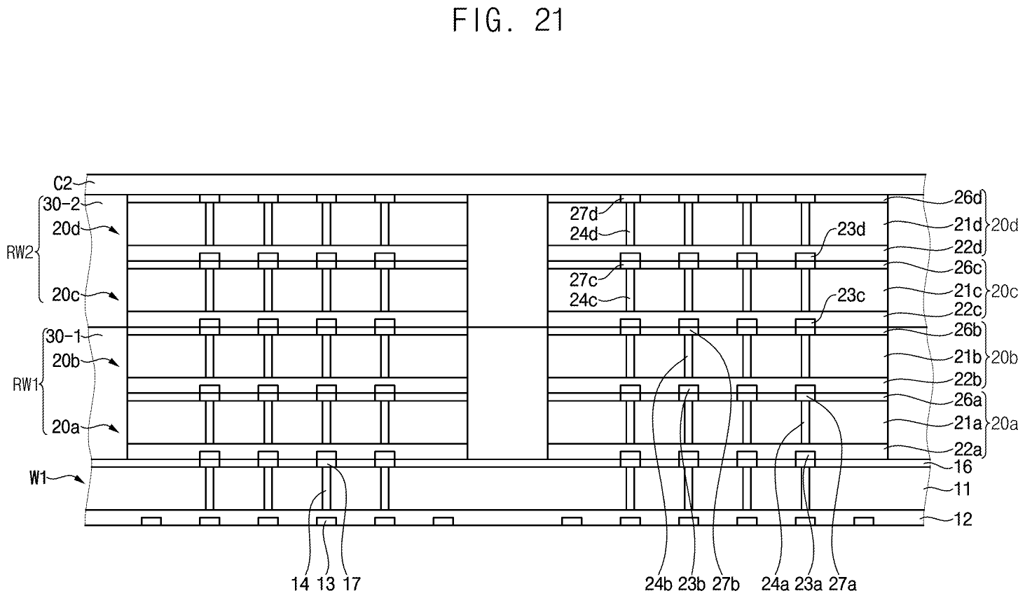

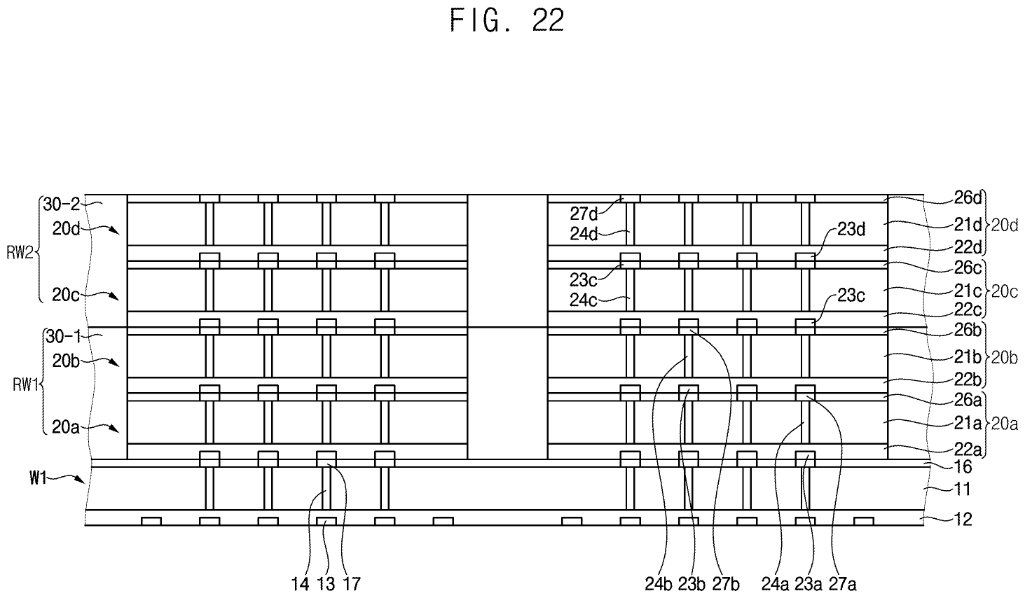

Referring to FIGS. 21 and 22, the second reconstructed wafer RW2 may be attached to the first reconstructed wafer RW1 on the first wafer W1 (wafer-to-wafer hybrid bonding process).

As illustrated in FIG. 21, the second reconstructed wafer RW2 of FIG. 20 may be bonded to the first reconstructed wafer RW1 on the first wafer W1. A front surface of the second intermediate core 20c of the second reconstructed wafer RW2 may be stacked to face the backside surface of the first intermediate core 20b of the first reconstructed wafer RW1.

When the second reconstructed wafer RW2 and the first reconstructed wafer RW1 are bonded to each other by wafer-to-wafer bonding, the second intermediate core 20c of the second reconstructed wafer RW2 and the first intermediate core 20b of the first reconstructed wafer RW1 may be hybrid-bonded to each other by a thermal compression process and an annealing process. That is, a first front insulating layer 22c on the front surface of the second intermediate core 20c may be directly bonded to a backside insulating layer 26b on the backside surface of the first intermediate core 20b, and a second bonding pad 27b of the first intermediate core 20b and a first bonding pad 23c of the second intermediate core 20c may be bonded to each other by copper-copper hybrid bonding (Cu—Cu Hybrid Bonding).

When the second reconstructed wafer RW2 and the first reconstructed wafer RW1 are bonded to each other by wafer-to-wafer bonding, the second gap filling portion 30-2 of the second reconstructed wafer RW2 and the first gap filling portion 30-1 of the first reconstructed wafer RW1 may be bonded to each other by a thermal compression process and an annealing process. By the annealing process, the first gap filling portion 30-1 and the second gap filling portion 30-2 may be directly bonded to each other to form a bonding interface layer. The bonding interface layer may have a thickness in a range of 2 Å to 500 Å. The bonding interface layer may include silicon oxide.

As illustrated in FIG. 22, the carrier substrate C2 may be removed to expose the backside surfaces of the second intermediate cores 20d of the second reconstructed wafer RW2. At this time, upper surfaces (backside surfaces) of the second intermediate cores 20d may be planarized to initialize a topology due to the stacking of the second intermediate cores 20c and 20d. For example, a chemical mechanical polishing (CMP) process may be performed to remove topology accumulation in bonding interfaces of the second intermediate cores 20d (topology reset process).

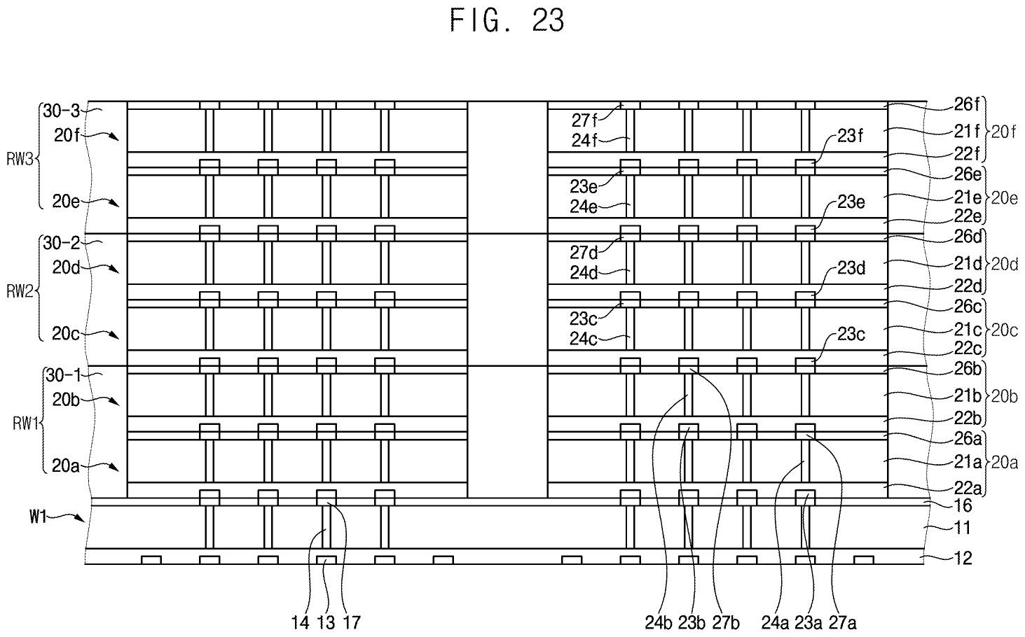

Referring to FIG. 23, processes the same as or similar to the processes described with reference to FIGS. 18 to 20 may be performed to form a third reconstructed wafer RW3 including at least one third intermediate core 20e, 20f and a third gap filing portion 30-3 covering an outer surface of the at least one third intermediate core 20e, 20f on a carrier substrate, and processes the same as or similar to the processes described with reference to FIGS. 21 and 22 may be performed to attach the third reconstructed wafer RW3 to the second reconstructed wafer RW2 (wafer-to-wafer hybrid bonding process).

In some implementations, the third intermediate cores 20e, 20f may be stacked in two stages on the carrier substrate and a filling layer may be formed to cover the third intermediate cores 20e and 20f, and an upper portion of the filling layer may be removed to form the third gap filling portion 30-3 that exposes upper surfaces of the second-stage third intermediate cores 20c. Then, upper surfaces of the second-stage third intermediate cores 20e may be planarized to initialize a topology due to the stacking of the third intermediate cores 20e and 20f For example, a chemical mechanical polishing (CMP) process may be performed to remove topology accumulation in bonding interfaces of the third-stage third intermediate cores 20e (topology reset process).

Then, the third reconstructed wafer RW3 may be stacked on the second reconstruction wafer RW2 such that a front surface of the third intermediate core 20e of the third reconstructed wafer RW3 faces the backside surface of the second intermediate core 20d of the second reconstructed wafer RW2.

When the third reconstructed wafer RW3 and the second reconstructed wafer RW2 are bonded to each other by wafer-to-wafer bonding, the third intermediate core 20e of the third reconstructed wafer RW3 and the second intermediate core 20d of the second reconstructed wafer RW2 may be hybrid-bonded to each other by a thermal compression process and an annealing process. That is, a first front insulating layer 22e on the front surface of the third intermediate core 20e may be directly bonded to a backside insulating layer 26d on the backside surface of the second intermediate core 20d, and a second bonding pad 27d of the second intermediate core 20d and a first bonding pad 23e of the third intermediate core 20e may be bonded to each other by copper-copper hybrid bonding (Cu—Cu Hybrid Bonding).

When the third reconstructed wafer RW3 and the second reconstructed wafer RW2 are bonded to each other by wafer-to-wafer bonding, the third gap filling portion 30-3 of the third reconstructed wafer RW2 and the second gap filling portion 30-2 of the second reconstructed wafer RW2 may be bonded to each other by a thermal compression process and an annealing process. By the annealing process, the second gap filling portion 30-2 and the third gap filling portion 30-3 may be directly bonded to each other to form a bonding interface layer. The bonding interface layer may have a thickness in a range of 2 Å to 500 Å. The bonding interface layer may include silicon oxide.

Then, the carrier substrate may be removed to expose the backside surfaces of the third intermediate cores 20f of the third reconstructed wafer RW3. At this time, upper surfaces (backside surfaces) of the third intermediate cores 20f may be planarized to initialize a topology due to the stacking of the third intermediate cores 20e and 20f For example, a chemical mechanical polishing (CMP) process may be performed to remove topology accumulation in bonding interfaces of the third intermediate cores 20f (topology reset process).

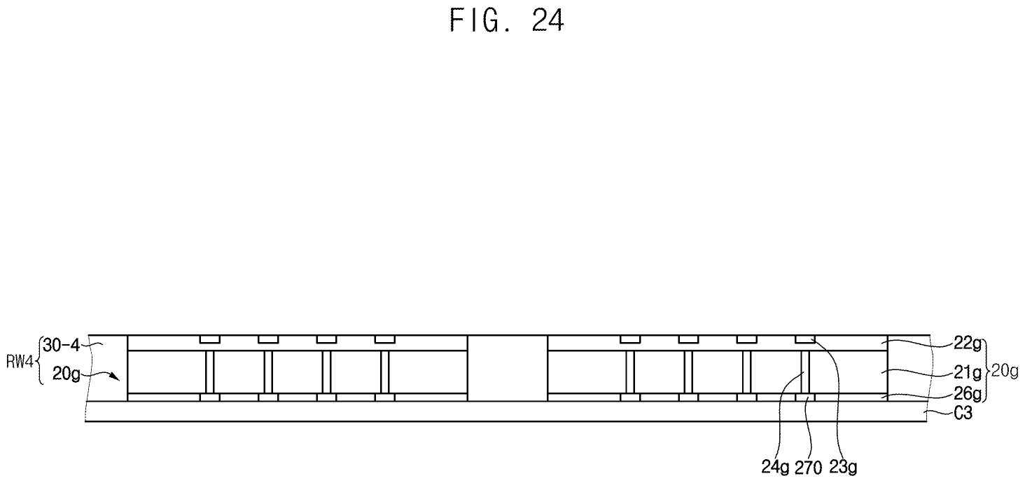

Referring to FIG. 24, a fourth reconstructed wafer RW4 including at least one fourth intermediate core 20g and a fourth gap filling portion 30-4 covering an outer surface of the at least one fourth intermediate core 20g may be formed on a carrier substrate C3. In this example, the fourth reconstructed wafer RW4 may include, but is not limited to, the fourth intermediate cores 20g stacked in one stage.

In some implementations, a plurality of the fourth intermediate cores 20g may be attached in one stage on the carrier substrate C3.

In particular, the fourth intermediate cores 20g may be disposed on the carrier substrate C3 to correspond to die region DA. The fourth intermediate core 20g may be stacked such that a second surface 214g of a substrate 21g of the fourth intermediate core 20g faces the carrier substrate C3.

Then, the fourth filling portion 30-4 may be formed to fill gaps between the fourth intermediate cores 20g stacked in one stage on the carrier substrate C3. A filling layer may be formed to cover the fourth intermediate cores 20g stacked in one stage on the carrier substrate C3, and an upper portion of the filling layer may be removed to form the fourth gap filling portion 30-4 that exposes upper surfaces of the first-stage fourth intermediate cores 20g. For example, the fourth gap filling portion 30-4 may be formed by a conformal deposition process such as an atomic layer deposition (ALD) process or a chemical vapor deposition (CVD) process. The fourth gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like. The upper portion of the filling layer may be removed by a chemical mechanical polishing process or a mechanical grinding process.

Accordingly, the fourth reconstructed wafer RW4 including the fourth intermediate cores 20g stacked in one stage and the fourth gap filling portion 30-4 covering the outer surfaces of the fourth intermediate cores 20g may be formed.

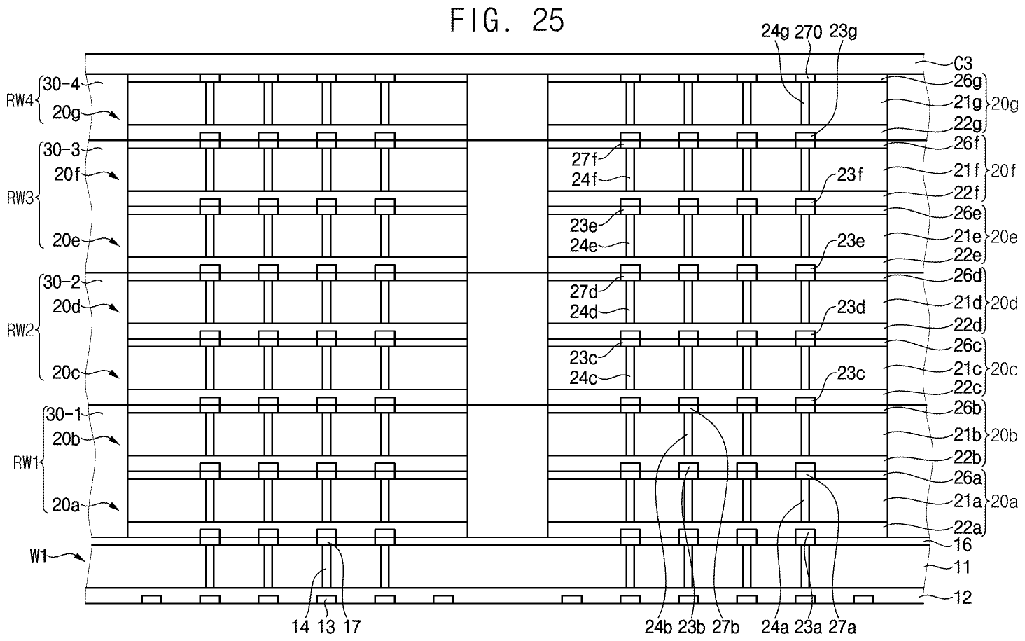

Referring to FIG. 25, the fourth reconstructed wafer RW4 may be attached to the third reconstructed wafer RW3 (wafer-to-wafer hybrid bonding process).

In some implementations, the fourth reconstructed wafer RW4 may be stacked on the third reconstruction wafer RW3 such that a front surface of the fourth intermediate core 20g of the fourth reconstructed wafer RW4 faces the backside surface of the third intermediate core 20f of the third reconstructed wafer RW3.

When the fourth reconstructed wafer RW4 and the third reconstructed wafer RW3 are bonded to each other by wafer-to-wafer bonding, the fourth intermediate core 20g of the fourth reconstructed wafer RW3 and the third intermediate core 20f of the third reconstructed wafer RW3 may be hybrid-bonded to each other by a thermal compression process and an annealing process. That is, a first front insulating layer 22g on the front surface of the fourth intermediate core 20g may be directly bonded to the backside insulating layer 26g on the backside surface of the third intermediate core 20f, and a second bonding pad 27f of the third intermediate core 20f and a first bonding pad 23g of the fourth intermediate core 20g may be bonded to each other by copper-copper hybrid bonding (Cu—Cu Hybrid Bonding).

When the fourth reconstructed wafer RW4 and the third reconstructed wafer RW3 are bonded to each other by wafer-to-wafer bonding, the fourth gap filling portion 30-4 of the fourth reconstructed wafer RW4 and the third gap filling portion 30-3 of the third reconstructed wafer RW3 may be bonded to each other by a thermal compression process and an annealing process. By the annealing process, the third gap filling portion 30-3 and the fourth gap filling portion 30-4 may be directly bonded to each other to form a bonding interface layer. The bonding interface layer may have a thickness in a range of 2 Å to 500 Å. The bonding interface layer may include silicon oxide.

Then, the carrier substrate C3 may be removed to expose the backside surfaces of the fourth intermediate cores 20g of the fourth reconstructed wafer RW4. At this time, upper surfaces (backside surfaces) of the fourth intermediate cores 20g may be planarized to initialize a topology due to the stacking of the fourth intermediate cores 20g. For example, a chemical mechanical polishing (CMP) process may be performed to remove topology accumulation in bonding interfaces of the fourth intermediate cores 20g (topology reset process).

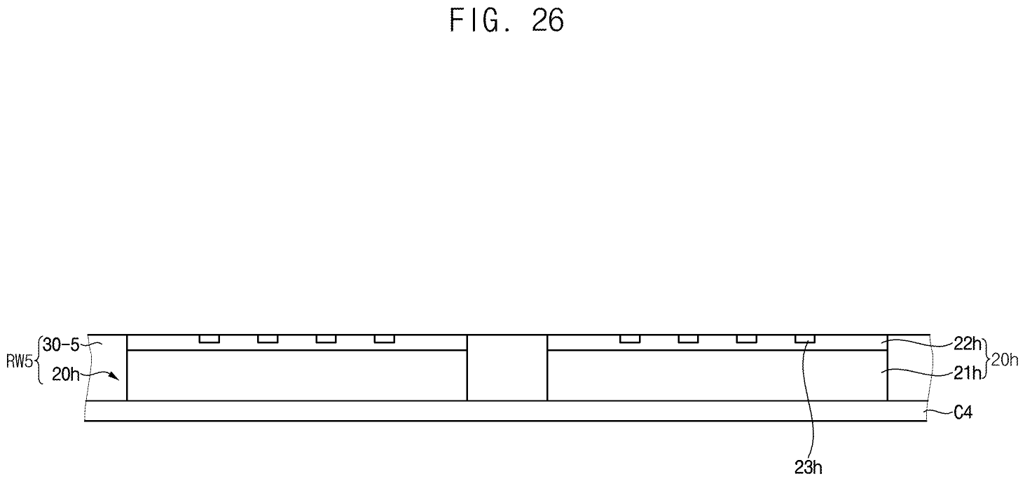

Referring to FIG. 26, a fifth reconstructed wafer RW5 including a top core 20h and a fifth gap filing portion 30-5 covering an outer surface of the top core 20h may be formed on a carrier substrate C4.

In some implementations, a plurality of the top cores 20h may be attached in one stage on the carrier substrate C4. A thickness of the top core 20h may be greater than thicknesses of the intermediate cores. The thickness of the top core 20h may be in a range of 100 μm to 300 μm. The thicknesses of the intermediate core dies 20a, 20b, and 20c may be in a range of 20 μm to 50 μm.

In particular, the top cores 20h may be disposed on the carrier substrate C4 to correspond to die region DA. The top cores 20h may be attached to the carrier substrate C4 using an adhesive film or an oxide layer. The top core 20h may be stacked such that a second surface 214h of a substrate 21h of the top core 20h faces the carrier substrate C4.

Then, the fifth filling portion 30-5 may be formed to fill gaps between the top cores 20h stacked in one stage on the carrier substrate C4. A filling layer may be formed to cover the top cores 20h stacked in one stage on the carrier substrate C4, and an upper portion of the filling layer may be removed to form the fifth gap filling portion 30-5 that exposes upper surfaces of the top cores 20h. For example, the fifth gap filling portion 30-5 may be formed by a conformal deposition process such as an atomic layer deposition (ALD) process or a chemical vapor deposition (CVD) process. The fifth gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like. The upper portion of the filling layer may be removed by a chemical mechanical polishing process or a mechanical grinding process.

Accordingly, the fifth reconstructed wafer RW5 including the top cores 20h stacked in one stage and the fifth gap filling portion 30-5 covering the outer surfaces of the top cores 20h may be formed.

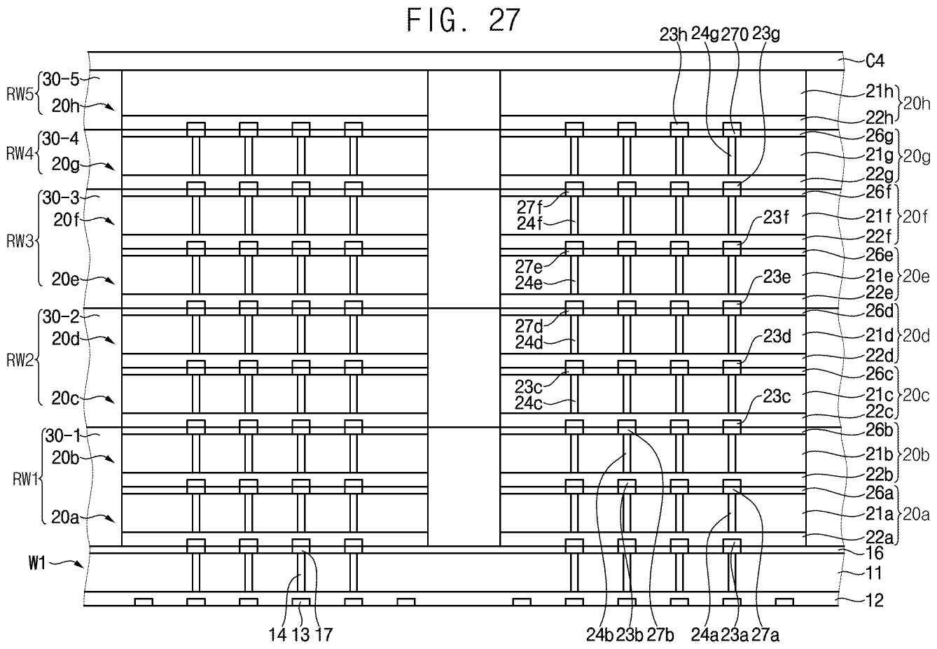

Referring to FIG. 27, the fifth reconstructed wafer RW5 may be attached to the fourth reconstructed wafer RW4 (wafer-to-wafer hybrid bonding process).

In some implementations, the fifth reconstructed wafer RW5 may be stacked on the fourth reconstruction wafer RW4 such that a front surface of the top core 20h of the fifth reconstructed wafer RW5 faces the backside surface of the fourth intermediate core 20g of the fourth reconstructed wafer RW4.

When the fifth reconstructed wafer RW5 and the fourth reconstructed wafer RW4 are bonded to each other by wafer-to-wafer bonding, the top core 20h of the fifth reconstructed wafer RW4 and the fourth intermediate core 20g of the fourth reconstructed wafer RW4 may be hybrid-bonded to each other by a thermal compression process and an annealing process. That is, a first front insulating layer 22h on the front surface of the top core 20h may be directly bonded to the backside insulating layer 26h on the backside surface of the fourth intermediate core 20g, and a second bonding pad 27g of the fourth intermediate core 20g and a first bonding pad 23h of the top core 20h may be bonded to each other by copper-copper hybrid bonding (Cu—Cu Hybrid Bonding).

When the fifth reconstructed wafer RW5 and the fourth reconstructed wafer RW4 are bonded to each other by wafer-to-wafer bonding, the fifth gap filling portion 30-5 of the fifth reconstructed wafer RW5 and the fourth gap filling portion 30-4 of the fourth reconstructed wafer RW4 may be bonded to each other by a thermal compression process and an annealing process. By the annealing process, the fourth gap filling portion 30-4 and the fifth gap filling portion 30-5 may be directly bonded to each other to form a bonding interface layer. The bonding interface layer may have a thickness in a range of 2 Å to 500 Å. The bonding interface layer may include silicon oxide.

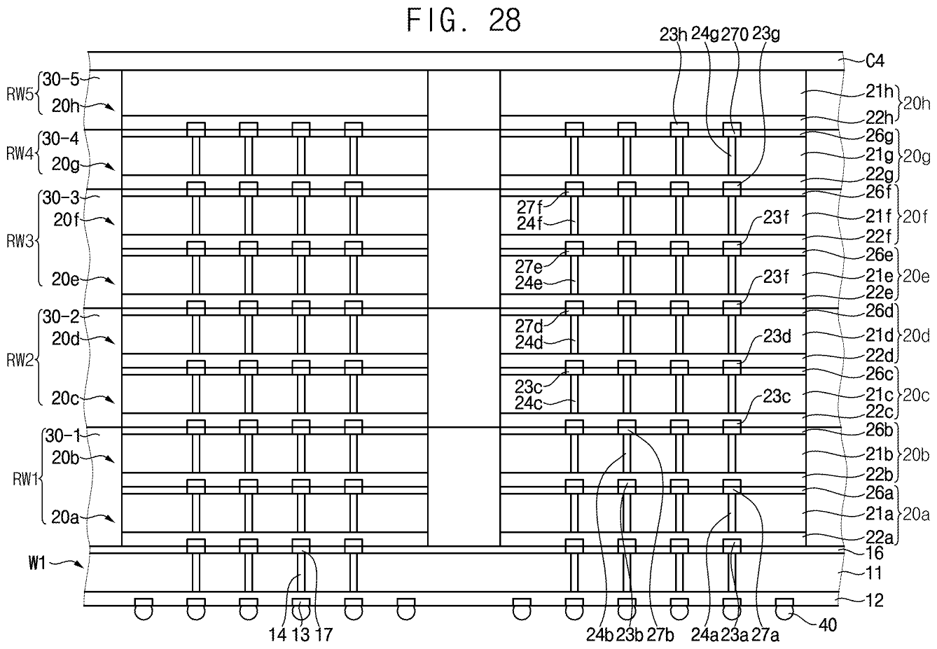

Referring to FIG. 28, conductive bumps 40 as conductive connection members may be formed on first bonding pads 13 of the first wafer W1.

For example, a seed layer may be formed on the first bonding pad 13 of the front insulating layer 12 of the first wafer W1, and a photoresist pattern having openings that expose portions of the seed layer may be formed on the seed layer on the front insulating layer 12. Then, the openings of the photoresist pattern may be filled up with a conductive material, the photoresist pattern may be removed and a reflow process may be performed to form solder bumps. For example, the conductive material may be formed on the seed layer by a plating process. Alternatively, the conductive bump may include a pillar bump and a solder bump formed on the pillar bump.

Then, the first wafer W1 and portions of the first to fifth gap filling portions 30-1, 30-2, 30-3, 30-4, and 30-5 may be cut along a scribe lane region SA to complete a semiconductor package 100 of FIG. 1.

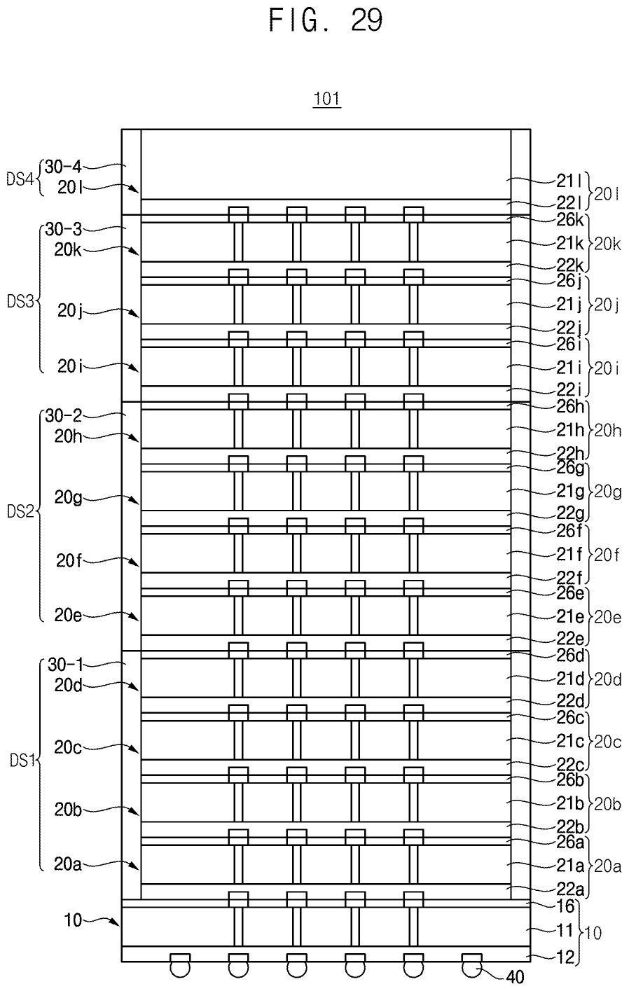

FIG. 29 is a cross-sectional view illustrating a semiconductor package. The semiconductor package is substantially the same as or similar to the semiconductor package described with reference to FIG. 1 except for the number of stacked core dies and a configuration of a gap filling portion. Thus, same reference numerals will be used to refer to the same or like elements and any further repetitive explanation concerning the above elements will be omitted.

Referring to FIG. 29, a semiconductor package 101 includes semiconductor chips (dies) 20 stacked therein. The semiconductor package 101 includes a buffer die 10, and first to third core die stacks DS1, DS2, and DS3 and a top core die stack DS4 sequentially stacked on the buffer die 10.

A plurality of semiconductor chips (dies) 20a, 20b, 20c, 20d, 20e, 20f, 20g, 20h, 20i, 20j, 20k, and 20l may be stacked vertically. In this example, the semiconductor chips (dies) 20a, 20b, 20c, 20d, 20e, 20f, 20g, 20h, 20i, 20j, 20k, and 20l may be substantially the same as or similar to each other. Accordingly, same or like reference numerals will be used to refer to the same or like elements and repeated descriptions of the same elements may be omitted.

In this example, the semiconductor package as a multi-chip package is illustrated as including twelve stacked semiconductor chips, e.g., cores 20a, 20b, 20c, 20d, 20e, 20f, 20g, 20h, 20i, 20j, 20k, and 20l, on the buffer die 10, however, the number is not limited thereto. For example, the semiconductor package may include 4, 8, or 16 stacked semiconductor chips.

Each of the semiconductor chips, e.g., cores 20a, 20b, 20c, 20d, 20e, 20f, 20g, 20h, 20i, 20j, 20k, and 20l, may include an integrated circuit chip completed by performing semiconductor manufacturing processes. Each semiconductor chip may include, for example, a memory chip or a logic chip. The semiconductor package 101 may include a memory device. The memory device may include a high bandwidth memory (HBM) device.

In some implementations, the first core die stack DS1 may be bonded onto the buffer die 10. The first core die stack DS1 may include first intermediate cores 20a, 20b, 20c, and 20d stacked in four stages and a first gap filling portion 30-1 covering outer surfaces of the first intermediate cores 20a, 20b, 20c, and 20d.

The second core die stack DS2 may be bonded onto the first core die stack DS1. The second core die stack DS2 may include second intermediate cores 20e, 20f, 20g, and 20h stacked in four stages and a second gap filling portion 30-2 covering outer surfaces of the second intermediate cores 20e, 20f, 20g, and 20h.

When the second core die stack DS2 and the first core die stack DS1 are bonded to each other, the second gap filling portion 30-2 of the second core die stack DS2 and the first gap filling portion 30-1 of the first core die stack DS1 may be bonded to each other by a thermal compression process and an annealing process. By the annealing process, the first gap filling portion 30-1 and the second gap filling portion 30-2 may be directly bonded to each other to form a bonding interface layer. The bonding interface layer may have a thickness in a range of 2 Å to 500 Å. The bonding interface layer may include silicon oxide.

The third core die stack DS3 may be bonded onto the second core die stack DS2. The third core die stack DS3 may include third intermediate cores 20i, 20j, and 20k stacked in three stages and a third gap filling portion 30-3 covering outer surfaces of the third intermediate cores 20i, 20j, and 20k.

When the third core die stack DS3 and the second core die stack DS2 are bonded to each other, the third gap filling portion 30-3 of the third core die stack DS3 and the second gap filling portion 30-2 of the second core die stack DS2 may be bonded to each other by a thermal compression process and an annealing process. By the annealing process, the second gap filling portion 30-2 and the third gap filling portion 30-3 may be directly bonded to each other to form a bonding interface layer. The bonding interface layer may have a thickness in a range of 2 Å to 500 Å. The bonding interface layer may include silicon oxide.

The top core die stack DS4 may be bonded to the third core die stack DS3. The top core die stack DS4 may include a top core die 20l stacked in one stage and a fourth gap filling portion 30-5 covering an outer surface of the top core die 20l. A thickness of the top core 20l may be greater than thicknesses of the intermediate cores 20a-20k. The thickness of the top core 20l may be in a range of 100 μm to 300 μm. The thicknesses of the intermediate core dies 20a-20l may be in a range of 20 μm to 50 μm.

When the top core die stack DS4 and the third core die stack DS3 are bonded to each other, the fourth gap filling portion 30-4 of the top core die stack DS4 and the third gap filling portion 30-3 of the third core die stack DS3 may be bonded to each other by a thermal compression process and an annealing process. By the annealing process, the third gap filling portion 30-3 and the fourth gap filling portion 30-4 may be directly bonded to each other to form a bonding interface layer. The bonding interface layer may include silicon oxide.

Hereinafter, a method of manufacturing the semiconductor package of FIG. 29 will be described.

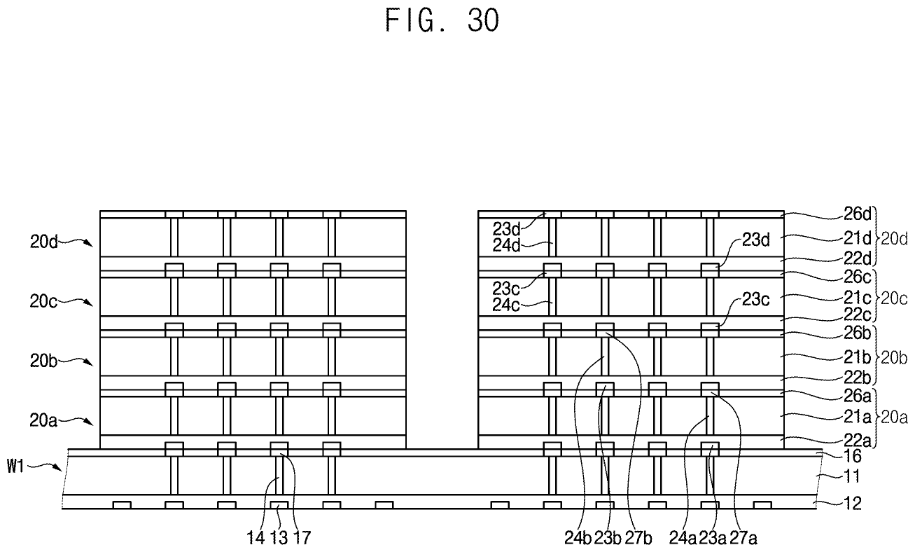

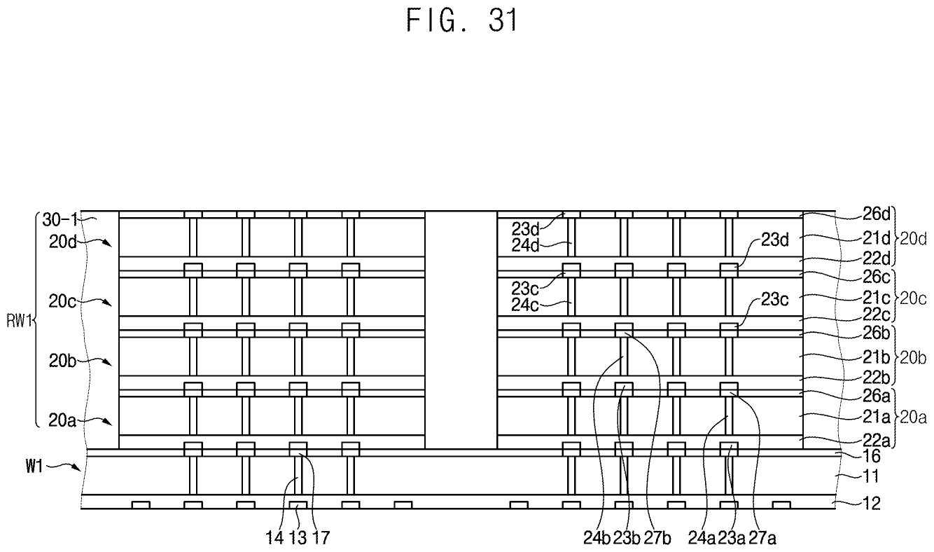

FIGS. 30 to 35 are views illustrating an example of a method of manufacturing a semiconductor package.

Referring to FIGS. 30 and 31, a first reconstructed wafer RW1 including at least one first intermediate core 20a, 20b, 20c, and 20d and a first gap filling portion 30-1 covering an outer surface of the at least one first intermediate core 20a, 20b, 20c, and 20d are formed on a first wafer 1. In this example, the first reconstructed wafer RW1 may include, but is not limited to, the first intermediate cores 20a, 20b, 20c, and 20d stacked in four stages.

As illustrated in FIG. 30, processes the same as or similar to the processes described with reference to FIGS. 13 to 16 may be performed to attach a plurality of the first intermediate cores 20a, 20b, 20c, and 20d in four stages on the first wafer W1 (die-to-wafer hybrid bonding process).

In some implementations, the first intermediate cores 20a may be disposed on the first wafer W1 to correspond to die region DA. The first intermediate core 20a may be stacked such that a first surface 212a of a substrate 21a faces the first wafer W1. By a thermal compression process, the first intermediate core 20a and the first wafer W1 may be bonded to each other through hybrid bonding.

Similarly, a plurality of the first intermediate cores 20b may be attached on the first-stage first intermediate cores 20a in a second stage, a plurality of the first intermediate cores 20c may be attached on the second-stage first intermediate cores 20b in a third stage, and a plurality of the first intermediate cores 20d may be attached on the third-stage first intermediate cores 20c in a fourth stage.

As illustrated in FIG. 31, processes the same as or similar to the processes described with reference to FIGS. 17 may be performed to form the first gap filling portion 30-1 that fills gaps between the first intermediate cores 20a, 20b, 20c, and 20d stacked in four stages on the first wafer W1.

A filling layer may be formed to cover the first intermediate cores 20a, 20b, 20c, and 20d stacked in four stages on the first wafer W1, and an upper portion of the filling layer may be removed to form the first gap filling portion 30-1 that exposes upper surfaces of the fourth-stage first intermediate cores 20d. For example, the first gap filling portion 30-1 may be formed by a conformal deposition process such as an atomic layer deposition (ALD) process or a chemical vapor deposition (CVD) process. The first gap filling portion may include an inorganic dielectric layer or an organic dielectric layer. The inorganic dielectric layer may include silicon oxide, silicon oxynitride, phosphosilicate glass (PSG), boro-phosphosilicate glass (BPSG), and other suitable/desired materials. The organic dielectric layer may include a polymer or the like. The upper portion of the filling layer may be removed by a chemical mechanical polishing process or a mechanical grinding process.

Then, an upper surface of the first reconstructed wafer RW1, e.g., the upper surfaces of the fourth-stage first intermediate cores 20c, may be planarized to initialize a topology due to the stacking of the first intermediate cores 20a, 20b, 20c, and 20d. For example, a chemical mechanical polishing (CMP) process may be performed to remove topology accumulation in bonding interfaces of the fourth-stage first intermediate cores 20d (topology reset process).

Accordingly, the first reconstructed wafer RW1 including the first intermediate cores 20a, 20b, 20c, and 20d stacked in four stages and the first gap filling portion 30-1 covering the outer surfaces of the first intermediate cores 20a, 20b, 20c, and 20d may be formed.

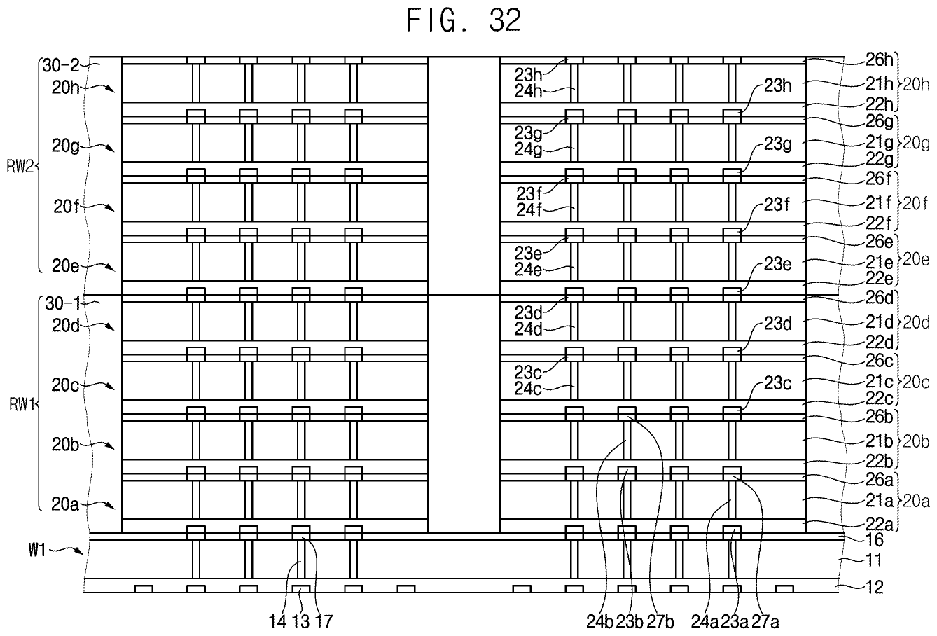

Referring to FIG. 32, processes the same as or similar to the processes described with reference to FIGS. 18 to 20 may be performed to form a second reconstructed wafer RW2 including at least one second intermediate core 20e, 20f, 20g, and 20h and a second gap filling portion 30-2 covering an outer surface of the at least one second intermediate core 20e, 20f, 20g, and 20h on a carrier substrate, and processes the same as or similar to the processes described with reference to FIGS. 21 and 22 may be performed to attach the second reconstruction wafer RW2 on the first reconstruction wafer RW1 (wafer-to-wafer hybrid bonding process).

In some implementations, the second intermediate cores 20e, 20f, 20g, and 20h may be attached in four stages on the carrier substrate and a filling layer may be formed to cover the second intermediate cores 20e, 20f, 20g, and 20h and an upper portion of the filling layer may be removed to form the second gap filling portion 30-2 that exposes upper surfaces of the fourth-stage second intermediate cores 20e. Then, upper surfaces of the fourth-stage second intermediate cores 20e may be planarized to initialize a topology due to the stacking of the second intermediate cores 20e, 20f, 20g, and 20h. For example, a chemical mechanical polishing (CMP) process may be performed to remove topology accumulation in bonding interfaces of the fourth-stage second intermediate cores 20e (topology reset process).

Then, the second reconstructed wafer RW2 may be stacked on the first reconstruction wafer RW1 such that a front surface of the second intermediate core 20e of the second reconstructed wafer RW2 faces the backside surface of the first intermediate core 20d of the first reconstructed wafer RW1.

When the second reconstructed wafer RW2 and the first reconstructed wafer RW1 are bonded to each other by wafer-to-wafer bonding, the second intermediate core 20e of the second reconstructed wafer RW2 and the first intermediate core 20d of the first reconstructed wafer RW1 may be hybrid-bonded to each other by a thermal compression process and an annealing process. That is, a first front insulating layer 22e on the front surface of the second intermediate core 20e may be directly bonded to a backside insulating layer 26d on the backside surface of the first intermediate core 20d, and a second bonding pad 27d of the first intermediate core 20d and a first bonding pad 23e of the second intermediate core 20e may be bonded to each other by copper-copper hybrid bonding (Cu—Cu Hybrid Bonding).

When the second reconstructed wafer RW2 and the first reconstructed wafer RW1 are bonded to each other by wafer-to-wafer bonding, the second gap filling portion 30-2 of the second reconstructed wafer RW2 and the first gap filling portion 30-1 of the first reconstructed wafer RW1 may be bonded to each other by a thermal compression process and an annealing process. By the annealing process, the first gap filling portion 30-1 and the second gap filling portion 30-2 may be directly bonded to each other to form a bonding interface layer. The bonding interface layer may have a thickness in a range of 2 Å to 500 Å. The bonding interface layer may include silicon oxide.

Then, the carrier substrate may be removed to expose backside surfaces of the second intermediate cores 20h of the second reconstructed wafer RW2. At this time, upper surfaces (backside surfaces) of the second intermediate cores 20h may be planarized to initialize a topology due to the stacking of the second intermediate cores 20e, 20f, 20g, and 20h. For example, a chemical mechanical polishing (CMP) process may be performed to remove topology accumulation in bonding interfaces of the second intermediate cores 20h (topology reset process).

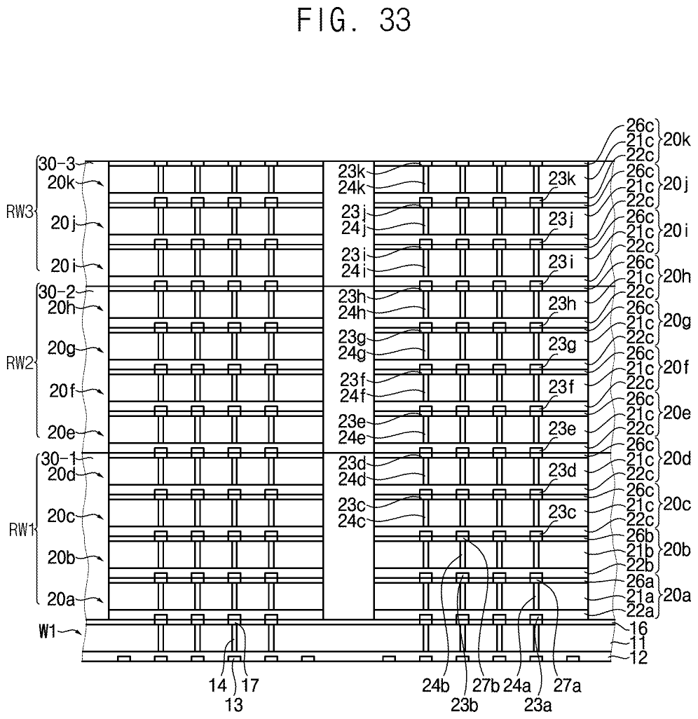

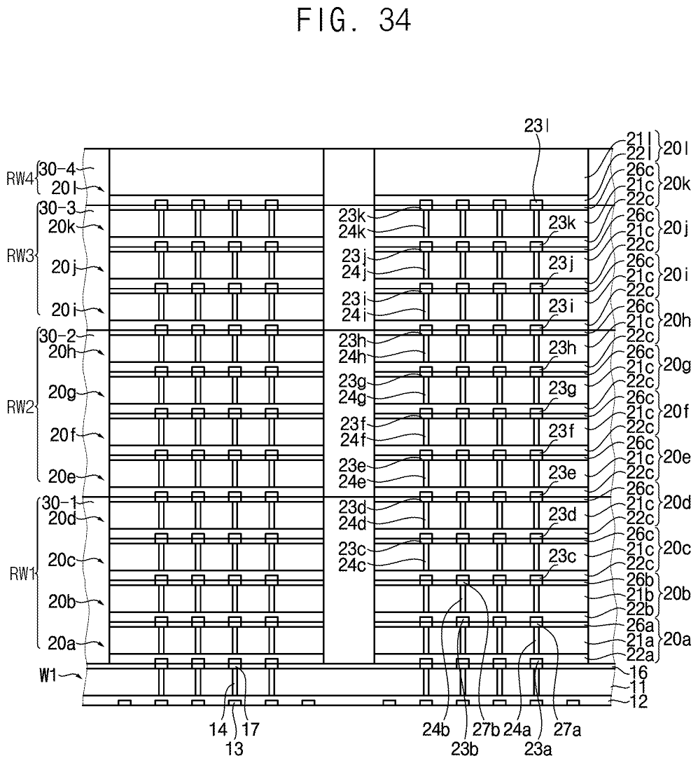

Referring to FIG. 33, processes the same as or similar to the processes described with reference to FIGS. 18 to 20 may be performed to form a third reconstructed wafer RW3 including at least one third intermediate core 20i, 20j, and 20k and a third gap filling portion 30-3 covering an outer surface of the at least one third intermediate core 20i, 20j, and 20k on a carrier substrate, and processes the same as or similar to the processes described with reference to FIGS. 21 and 22 may be performed to attach the third reconstruction wafer RW3 on the second reconstruction wafer RW2 (wafer-to-wafer hybrid bonding process).

In some implementations, the third intermediate cores 20i, 20j, and 20k may be attached in three stages on the carrier substrate and a filling layer may be formed to cover the third intermediate cores 20i, 20j, and 20k and an upper portion of the filling layer may be removed to form the third gap filling portion 30-3 that exposes upper surfaces of the fourth-stage third intermediate cores 20i. Then, upper surfaces of the fourth-stage third intermediate cores 20i may be planarized to initialize a topology due to the stacking of the third intermediate cores 20i, 20j, and 20k. For example, a chemical mechanical polishing (CMP) process may be performed to remove topology accumulation in bonding interfaces of the fourth-stage third intermediate cores 20i (topology reset process).

Then, the third reconstructed wafer RW3 may be stacked on the second reconstruction wafer RW2 such that a front surface of the third intermediate core 20i of the third reconstructed wafer RW3 faces the backside surface of the second intermediate core 20h of the second reconstructed wafer RW2.

When the third reconstructed wafer RW3 and the second reconstructed wafer RW2 are bonded to each other by wafer-to-wafer bonding, the third intermediate core 20i of the third reconstructed wafer RW3 and the second intermediate core 20h of the second reconstructed wafer RW2 may be hybrid-bonded to each other by a thermal compression process and an annealing process. That is, a first front insulating layer 22i on the front surface of the third intermediate core 20i may be directly bonded to a backside insulating layer 26h on the backside surface of the second intermediate core 20h, and a second bonding pad 27h of the second intermediate core 20h and a first bonding pad 23i of the third intermediate core 20i may be bonded to each other by copper-copper hybrid bonding (Cu—Cu Hybrid Bonding).

When the third reconstructed wafer RW3 and the second reconstructed wafer RW2 are bonded to each other by wafer-to-wafer bonding, the third gap filling portion 30-3 of the third reconstructed wafer RW3 and the second gap filling portion 30-2 of the second reconstructed wafer RW2 may be bonded to each other by a thermal compression process and an annealing process. By the annealing process, the second gap filling portion 30-2 and the third gap filling portion 30-3 may be directly bonded to each other to form a bonding interface layer. The bonding interface layer may have a thickness in a range of 2 Å to 500 Å. The bonding interface layer may include silicon oxide.

Then, the carrier substrate may be removed to expose backside surfaces of the third intermediate cores 20k of the third reconstructed wafer RW3. At this time, upper surfaces (backside surfaces) of the third intermediate cores 20k may be planarized to initialize a topology due to the stacking of the third intermediate cores 20i, 20j, and 20k. For example, a chemical mechanical polishing (CMP) process may be performed to remove topology accumulation in bonding interfaces of the third intermediate cores 20k (topology reset process).

Referring to FIG. 34, processes the same as or similar to the processes described with reference to FIG. 26 may be performed to form a fourth reconstructed wafer RW4 including a top core 20l and a fourth gap filling portion 30-4 covering an outer surface of the fourth intermediate core 20l on a carrier substrate, and processes the same as or similar to the processes described with reference to FIG. 27 may be performed to attach the fourth reconstruction wafer RW4 on the third reconstruction wafer RW3 (wafer-to-wafer hybrid bonding process).

In some implementations, a plurality of the top cores 20l may be attached in one stage on the carrier substrate and a filling layer may be formed to cover the top core 20l and an upper portion of the filling layer may be removed to form the fourth gap filling portion 30-4 that exposes upper surfaces of the top cores 20l. A thickness of the top core 20l may be greater than thicknesses of the intermediate cores. The thickness of the top core 20l may be in a range of 100 μm to 300 μm.

Then, the fourth reconstructed wafer RW4 may be stacked on the third reconstruction wafer RW3 such that a front surface of the top core 20l of the fourth reconstructed wafer RW4 faces the backside surface of the third intermediate core 20k of the third reconstructed wafer RW3.

When the fourth reconstructed wafer RW4 and the third reconstructed wafer RW3 are bonded to each other by wafer-to-wafer bonding, the top core 20l of the fourth reconstructed wafer RW4 and the third intermediate core 20k of the third reconstructed wafer RW3 may be hybrid-bonded to each other by a thermal compression process and an annealing process. That is, a first front insulating layer 22l on the front surface of the top core 20l may be directly bonded to a backside insulating layer 26k on the backside surface of the third intermediate core 20k, and a second bonding pad 27k of the third intermediate core 20k and a first bonding pad 23l of the top core 20l may be bonded to each other by copper-copper hybrid bonding (Cu—Cu Hybrid Bonding).

When the fourth reconstructed wafer RW4 and the third reconstructed wafer RW3 are bonded to each other by wafer-to-wafer bonding, the fourth gap filling portion 30-4 of the fourth reconstructed wafer RW4 and the third gap filling portion 30-3 of the third reconstructed wafer RW3 may be bonded to each other by a thermal compression process and an annealing process. By the annealing process, the third gap filling portion 30-3 and the fourth gap filling portion 30-4 may be directly bonded to each other to form a bonding interface layer. The bonding interface layer may have a thickness in a range of 2 Å to 500 Å. The bonding interface layer may include silicon oxide.

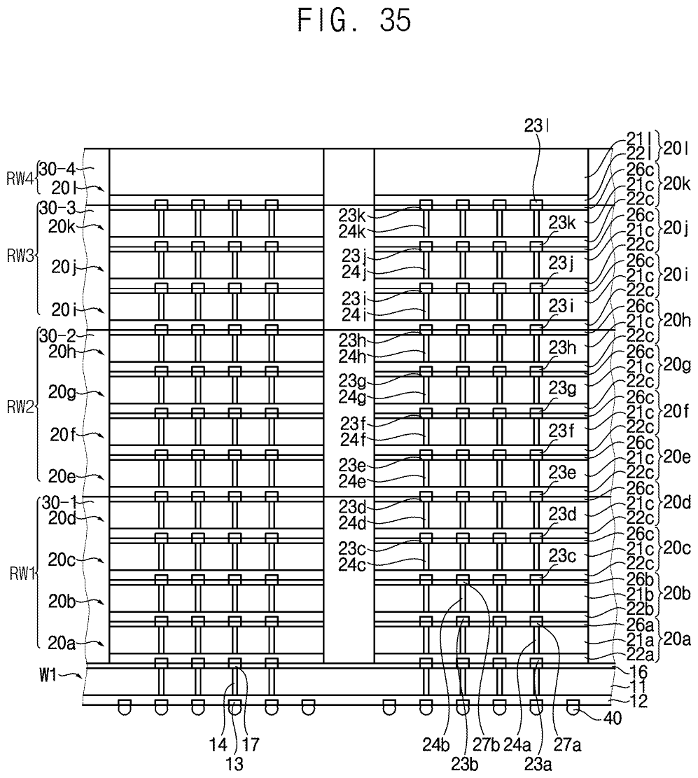

Referring to FIG. 35, conductive bumps 40 as conductive connection members may be formed on first bonding pads 13 of the first wafer W1.

Then, the first wafer W1 and portions of the first to fourth gap filling portions 30-1, 30-2, 30-3, and 30-4 may be cut along a scribe lane region SA to complete a semiconductor package 101 of FIG. 29.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

The foregoing is illustrative of example embodiments and is not to be construed as limiting thereof. Although a few example embodiments have been described, those skilled in the art will readily appreciate that many modifications are possible In some implementations without materially departing from the novel teachings and advantages of the present invention. Accordingly, all such modifications are intended to be included within the scope of example embodiments as defined in the claims.

1. A semiconductor package, comprising:
a buffer die;
a first core die stack stacked on the buffer die, the first core die stack including at least one first intermediate core and a first gap filling portion covering an outer surface of the at least one first intermediate core; and
a second core die stack stacked on the first core die stack, the second core die stack including at least one second intermediate core and a second gap filling portion covering an outer surface of the at least one second intermediate core,
wherein the first gap filling portion and the second gap filling portion are directly bonded to each other.

2. The semiconductor package of claim 1, wherein each of the at least one first intermediate core and the at least one second intermediate core includes:
a substrate;
a front insulating layer provided on a front surface of the substrate and having a first bonding pad; and
a backside insulating layer provided on a backside surface of the substrate and having a second bonding pad.

3. The semiconductor package of claim 2, wherein the backside insulating layer of the at least one first intermediate core is directly bonded to the front insulating layer of the at least one second intermediate core that is stacked on the at least one first intermediate core, and
wherein the second bonding pad of the at least one first intermediate core is directly bonded to the first bonding pad of the at least one second intermediate core that is stacked on the at least one first intermediate core.

4. The semiconductor package of claim 2, wherein the front insulating layer and the backside insulating layer include at least one of silicon oxide, silicon nitride, or silicon carbonitride.

5. The semiconductor package of claim 2, wherein each of the at least one first intermediate core and the at least one second intermediate core further includes a through electrode that penetrates the substrate and is electrically connected to the first and second bonding pads.

6. The semiconductor package of claim 1, wherein the first gap filling portion and the second gap filling portion include at least one of an inorganic dielectric or an organic dielectric.

7. The semiconductor package of claim 1, wherein the first gap filling portion and the second gap filling portion are directly bonded to each other and form a bonding interface layer.

8. The semiconductor package of claim 7, wherein the bonding interface layer has a thickness in a range of 2 Å to 500 Å.

9. The semiconductor package of claim 1, further comprising:
a top core die stack on the second core die stack, the top core die stack including a top core and a third gap filling portion covering an outer surface of the top core.

10. The semiconductor package of claim 9, wherein the third gap filling portion and the second gap filling portion are directly bonded to each other.

11. A semiconductor package, comprising:
a buffer die;
a first core die stack stacked on the buffer die, the first core die stack including at least one first intermediate core and a first gap filling portion covering an outer surface of the at least one first intermediate core;
a second core die stack stacked on the first core die stack, the second core die stack including at least one second intermediate core and a second gap filling portion covering an outer surface of the at least one second intermediate core; and
a top core die stack on the second core die stack, the top core die stack including a top core and a third gap filling portion covering an outer surface of the top core,
wherein each of the at least one first intermediate core and the at least one second intermediate core includes:
a substrate;
a front insulating layer provided on a front surface of the substrate and having a first bonding pad; and
a backside insulating layer provided on a backside surface of the substrate and having a second bonding pad, and
wherein the first gap filling portion and the second gap filling portion are directly bonded to each other.

12. The semiconductor package of claim 11, wherein the backside surface of the substrate of the at least one first intermediate core faces the front surface of the substrate of the at least one second intermediate core that is stacked on the at least one intermediate core.

13. The semiconductor package of claim 12, wherein the backside insulating layer of the at least one first intermediate core is directly bonded to the front insulating layer of the at least one second intermediate core that is stacked on the at least one first intermediate core, and
wherein the second bonding pad of the at least one first intermediate core is directly bonded to the first bonding pad of the at least one second intermediate core that is stacked on the at least one first intermediate core.

14. The semiconductor package of claim 11, wherein the front insulating layer and the backside insulating layer include at least one of silicon oxide, silicon nitride, or silicon carbonitride.

15. (canceled)

16. The semiconductor package of claim 11, wherein each of the at least one first intermediate core and the at least one second intermediate core further includes a through electrode that penetrates the substrate and is electrically connected to the first and second bonding pads.

17. The semiconductor package of claim 11, wherein the first gap filling portion and the second gap filling portion include at least one of an inorganic dielectric or an organic dielectric.

18. The semiconductor package of claim 11, wherein the first gap filling portion and the second gap filling portion are directly bonded to each other and form a bonding interface layer.

19. The semiconductor package of claim 18, wherein the bonding interface layer has a thickness in a range of 2 Å to 500 Å.

20. The semiconductor package of claim 11, wherein the third gap filling portion and the second gap filling portion are directly bonded to each other.

21. A semiconductor package, comprising:
a buffer die;
a plurality of core die stacks sequentially stacked on the buffer die; and
a top core die stack stacked on an uppermost core die stack of the plurality of core die stacks,
wherein each of the plurality of core die stacks includes at least one intermediate core and a gap filling portion covering an outer surface of the at least one intermediate core, and
wherein the at least one intermediate core includes:
a substrate;
a front insulating layer provided on a front surface of the substrate and having a first bonding pad; and
a backside insulating layer provided on a backside surface of the substrate and having a second bonding pad.

22.-30. (canceled)
